(19) United States
(12) Patent Application Publication
(10) Pub. No.: US 2011/0074608 A1
(43) Pub. Date: Mar. 31, 2011

(54) BUTTON-KEY DEVICE AND PORTABLE TERMINAL APPARATUS

(76) Inventor: Shingo Kawamura, Tokyo (JP)

(21) Appl. No.: 12/886,633

(22) Filed: Sep. 21, 2010

(30) Foreign Application Priority Data
Sep. 28, 2009 (JP) P2009-223529

(51) Int. Cl. H03K 17/94

(52) U.S. Cl. 341/22

(57) ABSTRACT

A button-key device includes a casing having an opening extending from a position near one end to a position near another end of the casing, and a pair of strength-maintaining projections projecting in opposite directions from the ends, respectively; a first key-top unit including a projecting section, an extended portion provided at an end of the projecting section facing one of the strength-maintaining projections, and flanges; a second key-top unit including a projecting section, an extended portion provided at an end of the projecting section facing the other strength-maintaining projection, and flanges; a first water-blocking sheet provided on a bottom of the first key-top unit; a second water-blocking sheet provided on a bottom of the second key-top unit and having an overlapping portion overlapping the first water-blocking sheet; and a pressing portion provided on the casing and pressed against the overlapping portion.

### BACKGROUND OF THE INVENTION

1. Field of the Invention

The present invention relates to button-key devices and portable terminal apparatuses suitable for application to electronic apparatuses having press-to-operate button keys, such as mobile phones, personal handyphone systems (PHSs), personal digital assistants (PDAs), portable game machines, digital cameras, moving-image-capturing apparatuses, and notebook and desktop personal computers.

In particular, the present invention relates to a button-key device and a portable terminal apparatus in which button keys are providable in a region having, in the lateral direction of a casing, a length substantially the same as that of the casing and in which the casing has sufficient strength.

2. Description of the Related Art

Today, there are many kinds of portable apparatuses, such as mobile phones, PHSs, PDAs, portable game machines, and digital cameras. In such portable apparatuses, operations including selection of items from menus and input of characters are usually performed with button keys that are pressed by users. In general, as in exemplary related-art apparatuses disclosed in Japanese Unexamined Patent Application Publications No. 2007-141076, No. 2008-166993, and No. 2009-123632, a button-key device includes the following: key tops made of resin or the like and projecting outside of a casing through an opening (where button keys are provided) of the casing; and a rubber sheet having pushers realizing direct turning on/off of switches provided on, for example, a substrate or a flexible-printed-circuit (FPC) board housed in the casing when the key tops are pressed.

The rubber sheet is in contact with the inner side of the casing and the substrate or the FPC board, thereby sealing gaps produced therebetween. Thus, the rubber sheet prevents water and dust from entering the interior of the casing through the opening where the key tops are provided, that is, the rubber sheet enhances waterproofness and dustproofness.

### SUMMARY OF THE INVENTION

The areas of key tops where fingers come into contact increase with the outside dimensions of the key tops. This advantageously improves the operability. On the other hand, the outside dimensions of key tops determine the size of the above-mentioned opening of the casing. Therefore, if the outside dimensions of key tops increase, the size of the opening of the casing also increases, resulting in a problematic reduction in the strength of the casing.

Specifically, if the outside dimensions of key tops are maximized for improved operability such that the key tops reach near ends of the casing, the size of the opening in which the key tops are to be provided is also maximized such that the opening reach near the ends of the casing. In such a case, since the casing provides its strength with the remaining portions at the ends thereof alone, it is difficult to maintain sufficient strength of the casing.

Moreover, to provide sufficient waterproofness and dustproofness by completely sealing the opening of the casing, the dimensions of a rubber sheet on which key tops are to be provided naturally become larger than the dimensions of the area occupied by the key tops.

If, however, the outside dimensions of key tops are maximized such that the key tops reach near the ends of the casing as described above, it becomes difficult to provide inside the casing a space sufficient for providing the rubber sheet whose dimensions are larger than the dimensions of the area occupied by the key tops. This problematically prevents provision of waterproofness and dustproofness using the rubber sheet.

The outside dimensions of key tops and the strength and waterproofness (dustproofness) of the casing trade each other off. In the related art, key tops are therefore provided at a certain distance from ends of the casing. Therefore, it is difficult to maximize the outside dimensions of the key tops such that the key tops reach near the ends of the casing.

Key tops, which are ones of members that determine the appearance of an apparatus, are desired to have various designs and shapes. Therefore, some of the structural problems described above may limit the designs of the key tops and the casing.

In light of the above, it is desirable that the present invention provides a button-key device and a portable terminal apparatus provided with a casing having sufficient strength and with sufficient waterproofness and dustproofness by using rubber sheets even if the outside dimensions of key tops are maximized such that the key tops reach near ends of the casing, and in which the allowance for the maximization of the outside dimensions of the key tops such that the key tops reach near the ends of the casing contributes to the flexible designs of the key tops and the casings.

To solve the above problems, according to an embodiment of the present invention, a button-key device includes the following elements: a casing having an opening provided by linearly and continuously cutting the casing from a position near one end to a position near another end, and a pair of strength-maintaining projections projecting in opposite directions from the ends, respectively, of the casing in a longitudinal direction of the opening; a first key-top unit including a projecting section projecting from the opening when the first key-top unit is fitted in the opening, an extended portion provided by extending an end of the projecting section, the end facing one of the strength-maintaining projections when the first key-top unit is fitted in the opening, and flanges projecting in opposite directions orthogonal to the longitudinal direction of the opening; a second key-top unit including a projecting section projecting from the opening when the second key-top unit is fitted in the opening, an extended portion provided by extending an end of the projecting section, the end facing the other strength-maintaining projection when the second key-top unit is fitted in the opening, and flanges projecting in opposite directions orthogonal to the longitudinal direction of the opening, the second key-top unit being provided such that a sum of lengths of the first and second key-top units in the longitudinal direction of the opening becomes substantially the same as a longitudinal length of the opening; a first water-blocking sheet provided on a bottom of the first key-top unit, the bottom being opposite the projecting section; a second water-blocking sheet provided on a bottom of the second key-top unit, the bottom being opposite the projecting section, the second water-blocking sheet having an overlapping portion that overlaps a portion of the first water-blocking sheet when the first and second key-top units are fitted in the opening; a pressing portion provided on the casing and applying a pressure to the overlapping portion by being in contact therewith; switches provided on a board housed in the casing and in correspondence with the first and second key-top units; a first pusher member provided between the first key-top unit and a corresponding one of the switches and configured to transmit to the switch a pressing force applied when the first key-top unit is pressed; and a second pusher member provided between the second key-top unit and the other corresponding switch and configured to transmit to the switch a pressing force applied when the second key-top unit is pressed.

In the above embodiment of the present invention, the pair of strength-maintaining projections provided on the casing project in opposite directions from the ends, respectively, of the casing in the longitudinal direction of the opening.

To fit the first key-top unit into the opening of the casing, the projecting section of the first key-top unit is made to project from the opening, and the first key-top unit is fitted into the opening of the casing such that the extended portion thereof is positioned above one of the strength-maintaining projections provided on the casing.

Likewise, to fit the second key-top unit into the opening of the casing, the projecting section of the second key-top unit is made to project from the opening, and the second key-top unit is fitted into the opening of the casing such that the extended portion thereof is positioned above the other strength-maintaining projection provided on the casing.

The opening of the casing is provided by linearly and continuously cutting the casing from a position near the one end to a position near the other end. The ends of the casing that define the opening are reinforced with the pair of strength-maintaining projections.

Therefore, the opening can be widened to extend from a position near the one end to a position near the other end of the casing while sufficient strength is provided to the ends of the casing that define the opening. Consequently, the outside dimensions of the key-top units to be provided in the opening can be increased.

In the above embodiment of the present invention, even if the outside dimensions of the key-top units are maximized such that the key-top units reach near the ends of the casing, sufficient strength of the casing and sufficient waterproofness and dustproofness by using the water-blocking sheets are provided. In other words, while sufficient strength of the casing and sufficient waterproofness and dustproofness by using the water-blocking sheets are provided, the outside dimensions of the key-top units can be maximized such that the key-top units reach near the ends of the casing.

The allowance for such maximization of the outside dimensions of the key-top units such that the key-top units reach near the ends of the casing contributes to the flexible designs of the key-top units and the casing.

Moreover, when the key-top units are fitted into the opening of the casing, the water-blocking sheets provided on the bottoms of the key-top units come into close contact with the edge of the opening. Thus, water and dust are prevented from entering the interior of the casing through the opening.

Furthermore, when the key-top units are fitted in the opening of the casing, the overlapping portion of the second water-blocking sheet provided on the bottom of the second key-top unit overlaps a portion of the first water-blocking sheet provided on the bottom of the first key-top unit. Furthermore, the pressing portion provided on the casing applies a pressure to the overlapping portion by being in contact therewith. Thus, water and dust are prevented from entering the interior of the casing through the gap produced between the key-top units.

### BRIEF DESCRIPTION OF THE DRAWINGS

FIG. 1 is a front view of a mobile phone according to an embodiment of the present invention;

FIG. 2 is an exploded perspective view of the mobile phone according to the embodiment;

FIG. 3A is a diagram for describing an opening provided in a front casing of the mobile phone according to the embodiment;

FIG. 3B is another diagram for describing the opening provided in the front casing of the mobile phone according to the embodiment;

FIG. 4A is a diagram for describing a first key-top unit provided in the opening of the front casing;

FIG. 4B is another diagram for describing the first key-top unit provided in the opening of the front casing;

FIG. 4C is another diagram for describing the first key-top unit provided in the opening of the front casing;

FIG. 4D is another diagram for describing the first key-top unit provided in the opening of the front casing;

FIG. 4E is another diagram for describing the first key-top unit provided in the opening of the front casing;

FIG. 5A is a diagram for describing a second key-top unit provided in the opening of the front casing;

FIG. 5B is another diagram for describing the second key-top unit provided in the opening of the front casing;

FIG. 5C is another diagram for describing the second key-top unit provided in the opening of the front casing;

FIG. 5D is another diagram for describing the second key-top unit provided in the opening of the front casing;

FIG. 5E is another diagram for describing the second key-top unit provided in the opening of the front casing;

FIG. 6 is a perspective view of a pusher unit provided in the mobile phone according to the embodiment;

FIG. 7A is a diagram for describing a process of fitting the first and second key-top units into the opening of the front casing;

FIG. 7B is another diagram for describing the process of fitting the first and second key-top units into the opening of the front casing;

FIG. 7C is another diagram for describing the process of fitting the first and second key-top units into the opening of the front casing;

FIG. 8 is a rear view of the front casing with the first and second key-top units fitted thereto;

FIG. 9A is a diagram for describing a state where the first and second key-top units fitted in the opening of the front casing overlap each other for sealing therebetween;

FIG. 9B is another diagram for describing the state where the first and second key-top units fitted in the opening of the front casing overlap each other for sealing therebetween;

FIG. 10 is a diagram for describing a state where a portion where the first and second key-top units overlap each other is pressed by a casing and how the pusher unit guides light;

FIG. 11 is a front view of a mobile phone according to a variation of the mobile phone according to the embodiment of the present invention;

FIG. 12A is a diagram for describing an intermediate key-top unit provided in the mobile phone according to the variation together with the first and second key-top units;

FIG. 12B is another diagram for describing the intermediate key-top unit provided in the mobile phone according to the variation together with the first and second key-top units;

FIG. 12C is another diagram for describing the intermediate key-top unit provided in the mobile phone according to the variation together with the first and second key-top units;

FIG. 12D is another diagram for describing the intermediate key-top unit provided in the mobile phone according to the variation together with the first and second key-top units;

FIG. 12E is another diagram for describing the intermediate key-top unit provided in the mobile phone according to the variation together with the first and second key-top units;

FIG. 13 is an exploded perspective view of the mobile phone according to the variation;

FIG. 14 is a perspective view of a pusher unit provided in the mobile phone according to the variation;

FIG. 15A is a diagram for describing a process of fitting the first, second, and intermediate key-top units to the front casing of the mobile phone according to the variation;

FIG. 15B is another diagram for describing the process of fitting the first, second, and intermediate key-top units to the front casing of the mobile phone according to the variation;

FIG. 15C is another diagram for describing the process of fitting the first, second, and intermediate key-top units to the front casing of the mobile phone according to the variation;

FIG. 15D is another diagram for describing the process of fitting the first, second, and intermediate key-top units to the front casing of the mobile phone according to the variation;

FIG. 16 is a rear view of the front casing of the mobile phone according to the variation with the first, second, and intermediate key-top units fitted thereto;

FIG. 17A is a diagram for describing a state where the first, second, and intermediate key-top units fitted in the opening of the front casing overlap each other for sealing therebetween;

FIG. 17B is another diagram for describing the state where the first, second, and intermediate key-top units fitted in the opening of the front casing overlap each other for sealing therebetween;

FIG. 18A is a diagram for describing a portion where water-blocking sheets provided on the first and second key-top units, respectively, overlap each other;

FIG. 18B is another diagram for describing the portion where the water-blocking sheets provided on the first and second key-top units, respectively, overlap each other;

FIG. 18C is another diagram for describing the portion where the water-blocking sheets provided on the first and second key-top units, respectively, overlap each other;

FIG. 18D is another diagram for describing the portion where the water-blocking sheets provided on the first and second key-top units, respectively, overlap each other;

FIG. 18E is another diagram for describing the portion where the water-blocking sheets provided on the first and second key-top units, respectively, overlap each other;

FIG. 18F is another diagram for describing the portion where the water-blocking sheets provided on the first and second key-top units, respectively, overlap each other;

FIG. 19 is a sectional view of the mobile phone according to the embodiment taken in the longitudinal direction thereof, showing relevant parts including the second key-top unit; and

FIG. 20 is a sectional view of the mobile phone according to the embodiment taken in the lateral direction thereof, showing relevant parts including the second key-top unit.

### DESCRIPTION OF THE PREFERRED EMBODIMENTS

The present invention is applicable to mobile phones.

### Configuration of Mobile Phone

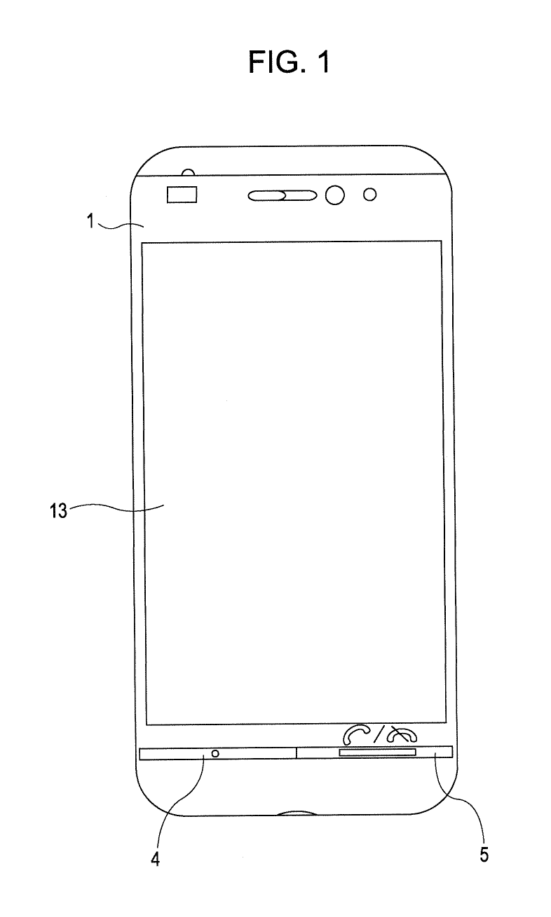

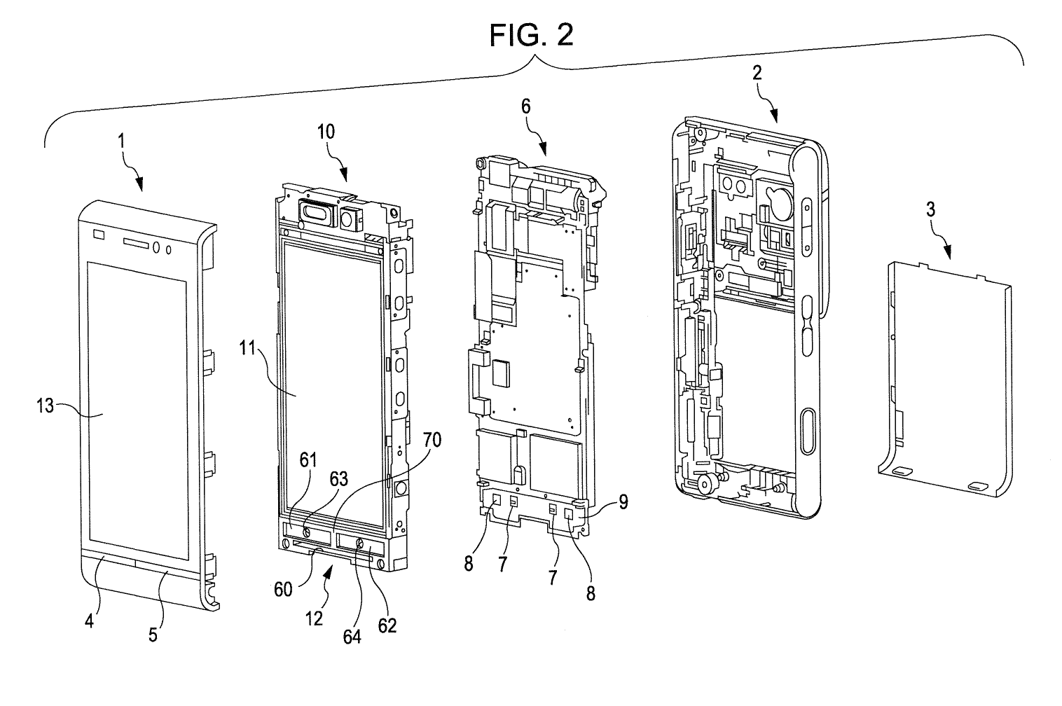

FIG. 1 is a front view of a mobile phone according to an embodiment of the present invention. FIG. 2 is an exploded perspective view of the mobile phone according to the embodiment. As can be seen from FIGS. 1 and 2, the mobile phone according to the embodiment has a casing formed by a front casing 1, a rear casing 2, and a back cover 3. A first key-top unit 4 and a second key-top unit 5 are fitted to the front casing 1.

A board 6 is housed in the casing. The board 6 is provided with a sheet key 9. The sheet key 9 is provided with two light-emitting diodes (LEDs) 7 that illuminate the key-top units 4 and 5, respectively, and dome switches 8 provided in correspondence with the key-top units 4 and 5. The board 6 is fitted to a frame 10 forming an internal structural body of the mobile phone, thereby being housed in the casing. The frame 10 is provided with a display unit 11 and a pusher-unit mount 12. A pusher unit that functions to push the dome switches 8 on the sheet key 9 is mounted on the pusher-unit mount 12. The front casing 1 is provided with a touch panel module 13 positioned over the display unit 11 provided on the frame 10.

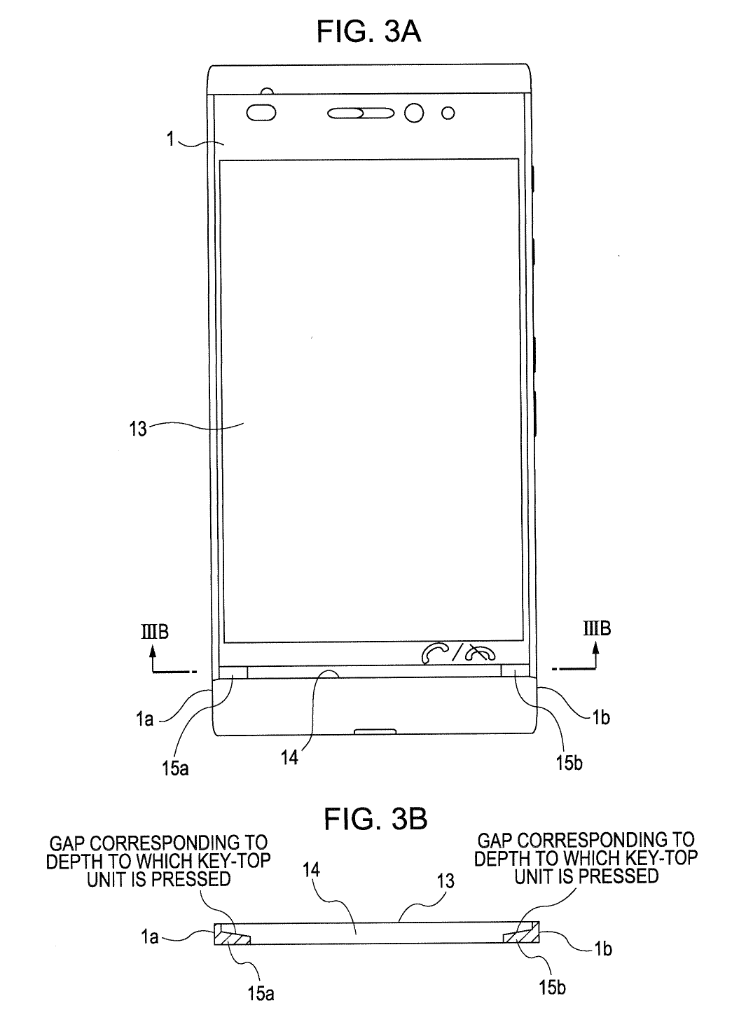

FIG. 3A is a front view of the front casing 1 without the first and second key-top units 4 and 5. FIG. 3B is a sectional view of the front casing 1, shown in FIG. 3A, taken along the line IIIB-IIIB. As can be seen from FIGS. 3A and 3B, the front casing 1 has an opening 14. The opening 14 is provided by linearly and continuously cutting the front casing 1 from a position proximate to an end 1a to a position proximate to another end 1b of the front casing 1.

The front casing 1 also has strength-maintaining projections 15a and 15b projecting in opposite directions from the ends 1a and 1b, respectively, in the longitudinal direction of the opening 14. The strength-maintaining projections 15a and 15b are each shaped such that a gap corresponding to a depth to which the key-top unit 4 or 5 is to be pressed is provided with respect to an extended portion, which will be described below, of the key-top unit 4 or 5.

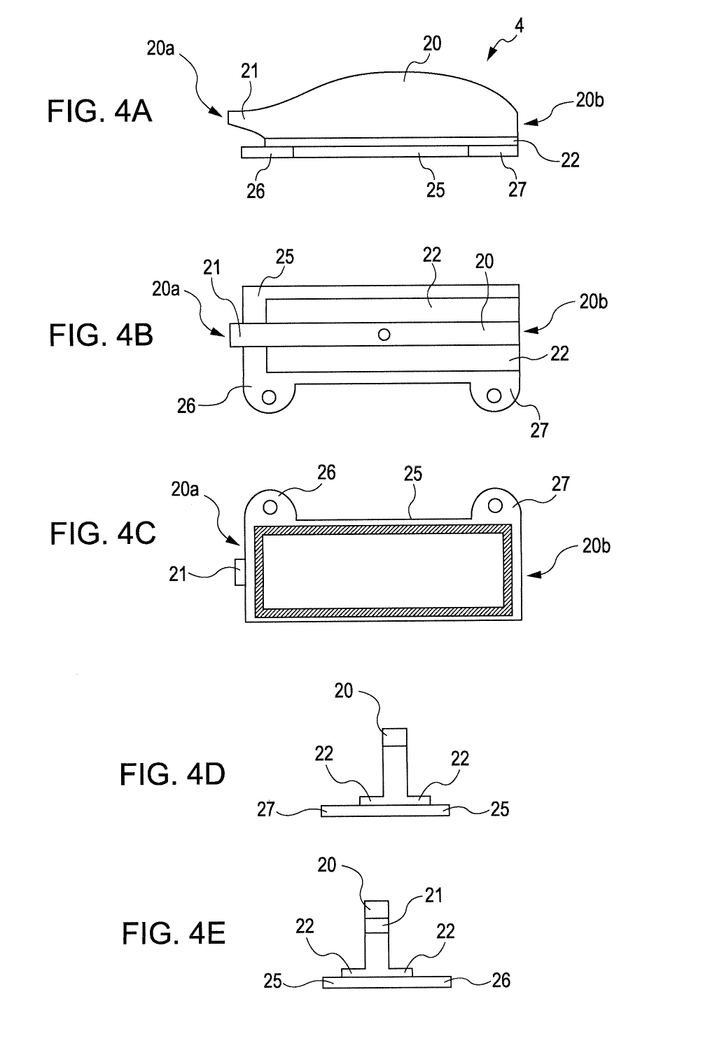

FIGS. 4A to 4E are a front view, a top view, a bottom view, a right-side view, and a left-side view, respectively, of the first key-top unit 4 to be fitted into the opening 14. As can be seen from FIGS. 4A to 4E, the first key-top unit 4 includes a projecting section 20 that is to project from the opening 14 when the first key-top unit 4 is fitted into the opening 14.

The first key-top unit 4 also includes an extended portion 21 and flanges 22. Ends of the projecting section 20 in the longitudinal direction of the opening 14 are referred to as an end 20a and an end 20b. The end 20a is extended to form the extended portion 21. When the first key-top unit 4 is fitted into the opening 14, the end 20a faces the strength-maintaining projection 15a with the aforementioned gap interposed therebetween, the gap corresponding to the depth to which the first key-top unit 4 is to be pressed. The flanges 22 project in opposite directions that are orthogonal to the longitudinal direction of the opening 14 so that the first key-top unit 4 does not come off from the opening 14 when the projecting section 20 is made to project from the opening 14.

The first key-top unit 4 is provided on the bottom thereof, i.e., a surface thereof opposite the projecting section 20, with a first water-blocking sheet 25 bonded thereto. The first water-blocking sheet 25 has a larger area than the bottom surface of the first key-top unit 4, and is made of a waterproof rubber material or the like processed into a substantially rectangular shape with a pair of securing tabs 26 and 27 at which the first water-blocking sheet 25 is secured to the front casing 1 together with the first key-top unit 4. Furthermore, as shown in FIG. 4C, the first water-blocking sheet 25 has shading treatment done with, for example, black ink along the periphery thereof. With the shading treatment, light from a corresponding one of the LEDs 7 is efficiently guided toward the first key-top unit 4.

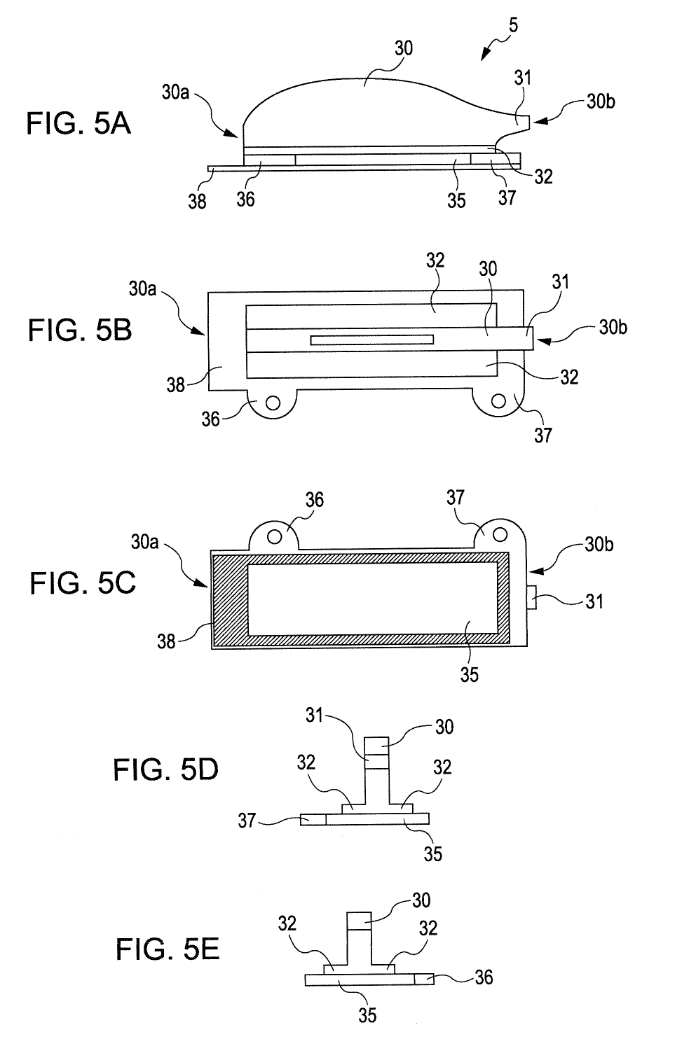

FIGS. 5A to 5E are a front view, a top view, a bottom view, a right-side view, and a left-side view, respectively, of the second key-top unit 5 to be fitted into the opening 14. As can be seen from FIGS. 5A to 5E, the second key-top unit 5 includes a projecting section 30 that is to project from the opening 14 when the second key-top unit 5 is fitted into the opening 14.

The second key-top unit 5 also includes an extended portion 31 and flanges 32. Ends of the projecting section 30 in the longitudinal direction of the opening 14 are referred to as an end 30a and an end 30b. The end 30b is extended to form the extended portion 31. When the second key-top unit 5 is fitted into the opening 14, the end 30b faces the strength-maintaining projection 15b with the aforementioned gap interposed therebetween, the gap corresponding to the depth to which the second key-top unit 5 is to be pressed. The flanges 32 project in opposite directions that are orthogonal to the longitudinal direction of the opening 14 so that the second key-top unit 5 does not come off from the opening 14 when the projecting section 30 is made to project from the opening 14.

The second key-top unit 5 is provided on the bottom thereof, i.e., a surface thereof opposite the projecting section 30, with a second water-blocking sheet 35 bonded thereto. The second water-blocking sheet 35 has a larger area than the bottom surface of the second key-top unit 5, and is made of a waterproof rubber material or the like processed into a substantially rectangular shape with a pair of securing tabs 36 and 37 at which the second water-blocking sheet 35 is secured to the front casing 1 together with the second key-top unit 5.

Furthermore, the second water-blocking sheet 35 has an overlapping portion 38 that overlaps a portion of the first water-blocking sheet 25 when the second key-top unit 5 is fitted into the opening 14 together with the first key-top unit 4.

Furthermore, as shown in FIG. 5C, the second water-blocking sheet 35 has shading treatment done with, for example, black ink along the periphery thereof. With the shading treatment, light from a corresponding one of the LEDs 7 is efficiently guided toward the second key-top unit 5.

The first and second key-top units 4 and 5 have substantially the same length and are shaped such that, in the longitudinal direction of the opening 14, the sum of the lengths of the key-top units 4 and 5 becomes substantially the same as the length of the opening 14 in a state where the key-top units 4 and 5 are fitted in the opening 14.

In this embodiment, the key-top units 4 and 5 have substantially the same length. Alternatively, as long as the sum of the lengths of the key-top units 4 and 5 is substantially the same as the length of the opening 14 in the longitudinal direction of the opening 14, the first key-top unit 4 may be longer than the second key-top unit 5, or conversely the second key-top unit 5 may be longer than the first key-top unit 4.

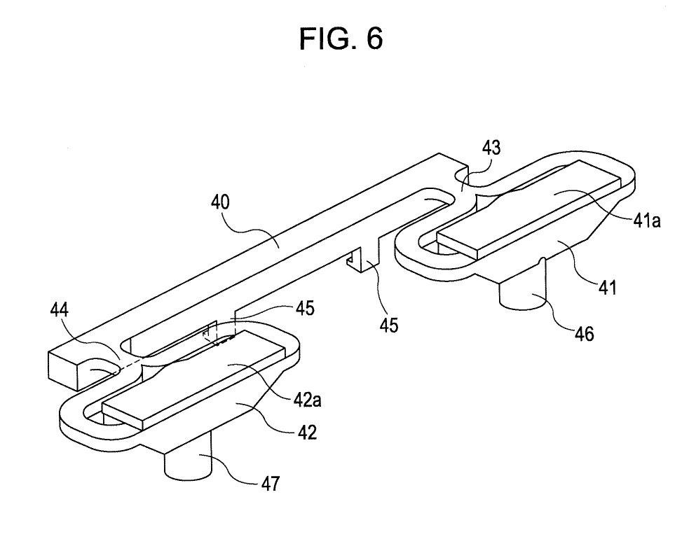

The pusher unit to be mounted on the pusher-unit mount 12 of the frame 10 shown in FIG. 2 includes, referring now to FIG. 6, a connecting bar 40 having a substantially stick-like shape, a first pusher member 41, and a second pusher member 42. The first pusher member 41 has a first projection 46 and is to be positioned between the first key-top unit 4 and the dome switch 8 corresponding thereto. When the first key-top unit 4 is pressed, the pressing force is transmitted to the dome switch 8 through the first projection 46. The second pusher member 42 has a second projection 47 and is to be positioned between the second key-top unit 5 and the dome switch 8 corresponding thereto. When the second key-top unit 5 is pressed, the pressing force is transmitted to the dome switch 8 through the second projection 47.

The pusher unit also includes a first supporting portion 43, a second supporting portion 44, and a pair of locking hooks 45. The first supporting portion 43 connects the first pusher member 41 to the connecting bar 40 and bends in response to the pressing of the first key-top unit 4. The second supporting portion 44 connects the second pusher member 42 to the connecting bar 40 and bends in response to the pressing of the second key-top unit 5. The locking hooks 45 are provided on the connecting bar 40 and secure the pusher unit to the frame 10.

The pusher unit is formed such that the connecting bar 40, the first pusher member 41, the first supporting portion 43, the second pusher member 42, and the second supporting portion 44 are integrally molded from, for example, a transparent or translucent light-conducting material, such as polycarbonate resin, that bends when a force is applied thereto and restores the original shape when the applied force is removed.

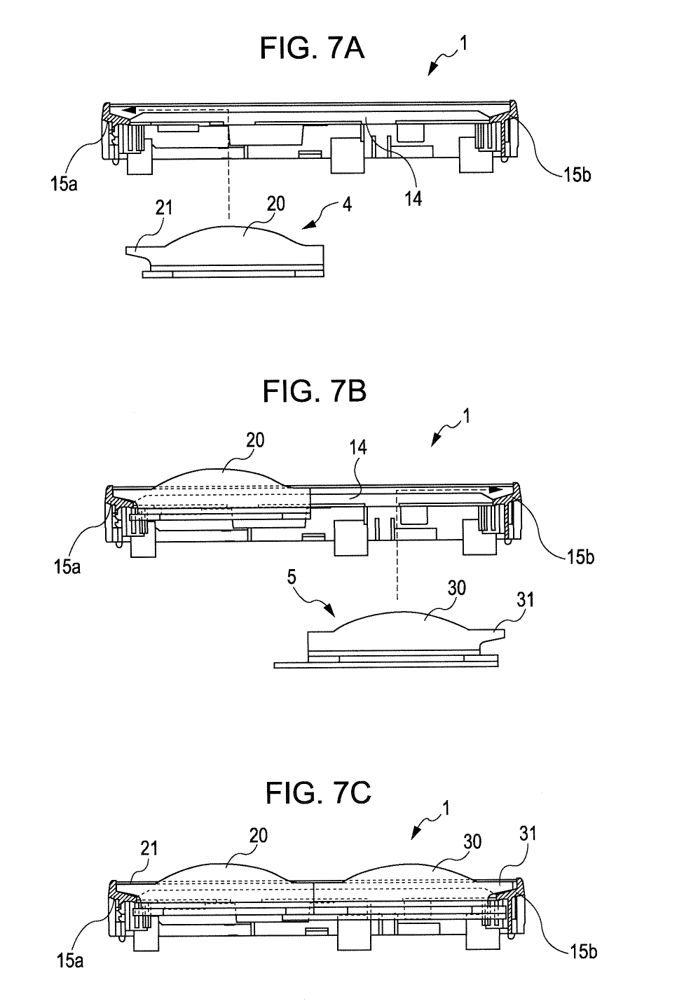

FIGS. 7A to 7C show a process of fitting the key-top units 4 and 5 to the front casing 1. FIGS. 7A to 7C are sectional views of the front casing 1 taken along the opening 14.

To fit the first key-top unit 4 to the front casing 1, referring to FIG. 7A, the projecting section 20 of the first key-top unit 4 is inserted into the opening 14 from the back of the front casing 1. Thus, the projecting section 20 of the first key-top unit 4 projects from the opening 14, with the flanges 22 of the first key-top unit 4 being caught at the opening 14. In this state, the first key-top unit 4 is slid toward the strength-maintaining projection 15a of the front casing 1 so that the extended portion 21 of the first key-top unit 4 is positioned above the strength-maintaining projection 15a.

Subsequently, referring to FIG. 7B, the extended portion 31 of the second key-top unit 5 is hooked over the strength-maintaining projection 15b from the back of the front casing 1. In this state, the second key-top unit 5 is pressed from the bottom thereof toward the opening 14. Thus, the projecting section 30 of the second key-top unit 5 projects from the opening 14, with the flanges 32 of the second key-top unit 5 being caught at the opening 14.

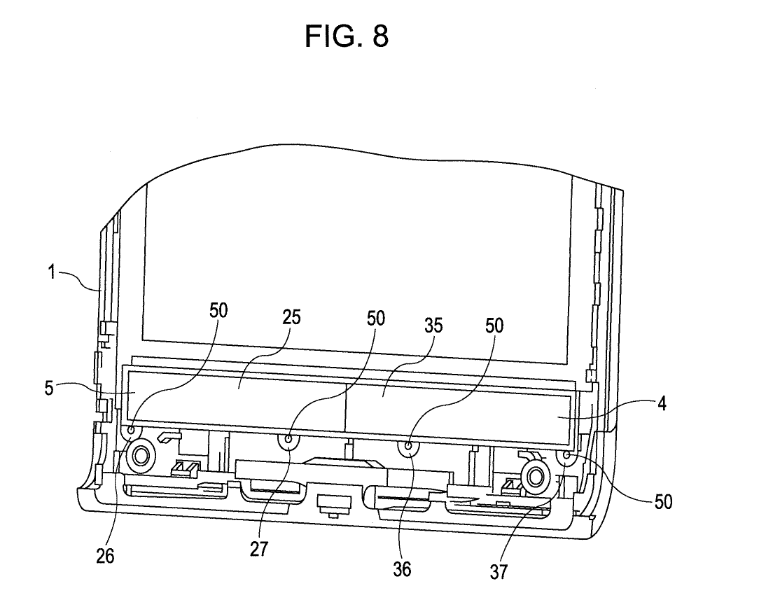

When the first key-top unit 4 is slid toward the strength-maintaining projection 15a of the front casing 1 such that the extended portion 21 is positioned above the strength-maintaining projection 15a and subsequently the extended portion 31 of the second key-top unit 5 is hooked over the strength-maintaining projection 15b of the front casing 1 and then the second key-top unit 5 is pressed from the bottom thereof toward the opening 14, referring now to FIG. 8, the pair of securing tabs 26 and 27 of the first water-blocking sheet 25 and the pair of securing tabs 36 and 37 of the second water-blocking sheet 35 engage with projections 50, respectively, provided on the front casing 1. Thus, the key-top units 4 and 5 are secured to the front casing 1 at the opening 14.

The opening 14 of the front casing 1 is provided by linearly and continuously cutting the front casing 1 from a position near the end 1a to a position near the end 1b of the front casing 1. Furthermore, the ends 1a and 1b of the front casing 1 that define the opening 14 are reinforced with the pair of strength-maintaining projections 15a and 15b.

Therefore, the opening 14 can be widened to extend from a position near the end 1a to a position near the end 1b of the front casing 1 while sufficient strength is provided to the ends 1a and 1b of the front casing 1 that define the opening 14. Consequently, the outside dimensions of the key-top units 4 and 5 to be provided in the opening 14 can be increased.

The allowance for such maximization of the outside dimensions of the key-top units 4 and 5 such that the key-top units 4 and 5 reach near the ends 1a and 1b of the front casing 1 contributes to the flexible designs of the key-top units 4 and 5 and the casing.

Moreover, when the key-top units 4 and 5 are fitted into the opening 14 of the front casing 1, the water-blocking sheets 25 and 35 provided on the bottoms of the key-top units 4 and 5 come into close contact with the edge of the opening 14. Thus, water and dust are prevented from entering the interior of the casing through the opening 14.

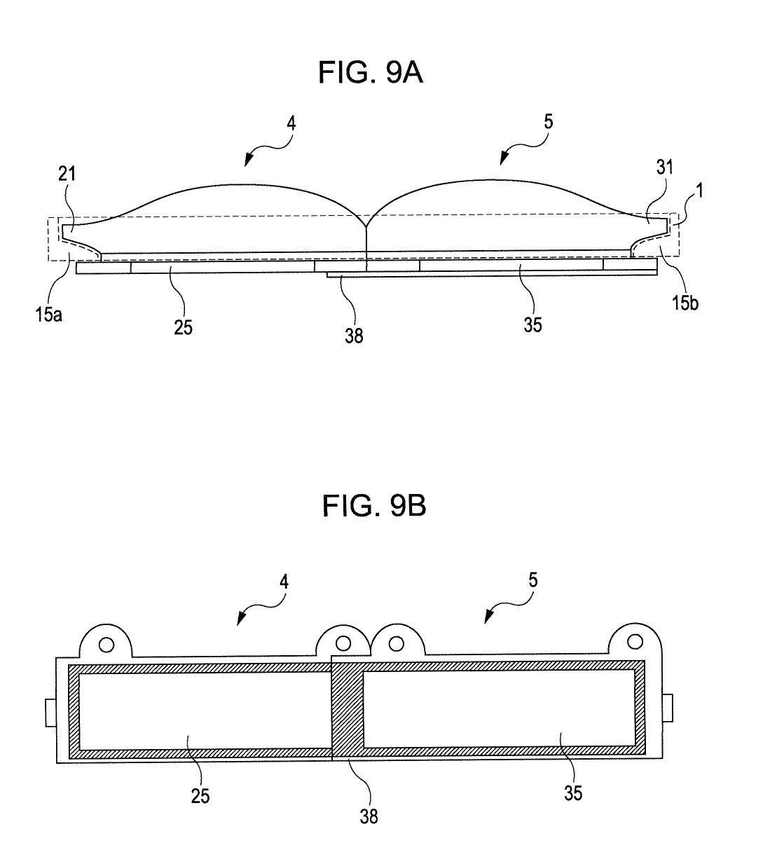

FIG. 9A is a side view of the key-top units 4 and 5 fitted in the opening 14 of the front casing 1. FIG. 9B is a bottom view of the key-top units 4 and 5 fitted in the opening 14 of the front casing 1. As can be seen from FIGS. 9A and 9B, when the key-top units 4 and 5 are fitted in the opening 14 of the front casing 1, the overlapping portion 38 of the second water-blocking sheet 35 provided on the second key-top unit 5 overlaps a portion of the first water-blocking sheet 25 provided on the first key-top unit 4. A pressing portion 70, shown in FIG. 2 and described below, provided on the frame 10 comes into contact with the overlapping portion 38. With the pressing portion 70 pressing the overlapping portion 38, water and dust are prevented from entering the interior of the casing through a gap between the key-top units 4 and 5.

A process of mounting the pusher unit onto the frame 10 will now be described. Referring to FIG. 2, the frame 10 has the pusher-unit mount 12 including a groove 60 that receives the connecting bar 40 of the pusher unit, described above referring to FIG. 6, a concave-shaped first-pusher-member-receiving portion 61 that receives the first pusher member 41, and a concave-shaped second-pusher-member-receiving portion 62 that receives the second pusher member 42.

The first-pusher-member-receiving portion 61 has a hole 63 into which the first projection 46 of the first pusher member 41 is to be inserted. The second-pusher-member-receiving portion 62 has a hole 64 into which the second projection 47 of the second pusher member 42 is to be inserted.

The groove 60 is provided with locking holes (not shown) to which the pair of locking hooks 45 of the pusher unit shown in FIG. 6 are to be hooked, respectively.

To mount the pusher unit onto the pusher-unit mount 12, the connecting bar 40 of the pusher unit is fitted into the groove 60, the first projection 46 of the first pusher member 41 is then inserted into the hole 63 of the first-pusher-member-receiving portion 61, and the first pusher member 41 is then fitted into the first-pusher-member-receiving portion 61. Meanwhile, the second projection 47 of the second pusher member 42 is inserted into the hole 64 of the second-pusher-member-receiving portion 62, and the second pusher member 42 is then fitted into the second-pusher-member-receiving portion 62.

Thus, the pair of locking hooks 45 shown in FIG. 6 are hooked into the locking holes provided in the groove 60. Consequently, the pusher unit is secured to the pusher-unit mount 12 of the frame 10.

To assemble the mobile phone, with the key-top units 4 and 5 fitted to the front casing 1 and the pusher unit mounted on the pusher-unit mount 12 of the frame 10 as described above, the frame 10 and the board 6 are housed together in the casing formed by the front casing 1 and the rear casing 2, shown in FIG. 2, and the back cover 3 is then put to the rear casing 2. Thus, the mobile phone is assembled.

As shown in FIG. 2, a portion of the frame 10 between the first-pusher-member-receiving portion 61 and the second-pusher-member-receiving portion 62 forms the pressing portion 70, which has a convex shape. When the frame 10 is placed inside the casing formed by the front casing 1 and the rear casing 2, the pressing portion 70 comes into contact with the overlapping portion 38 where the key-top units 4 and 5 fitted to the front casing 1 overlap each other, thereby pressing the overlapping portion 38 with a specific pressure.

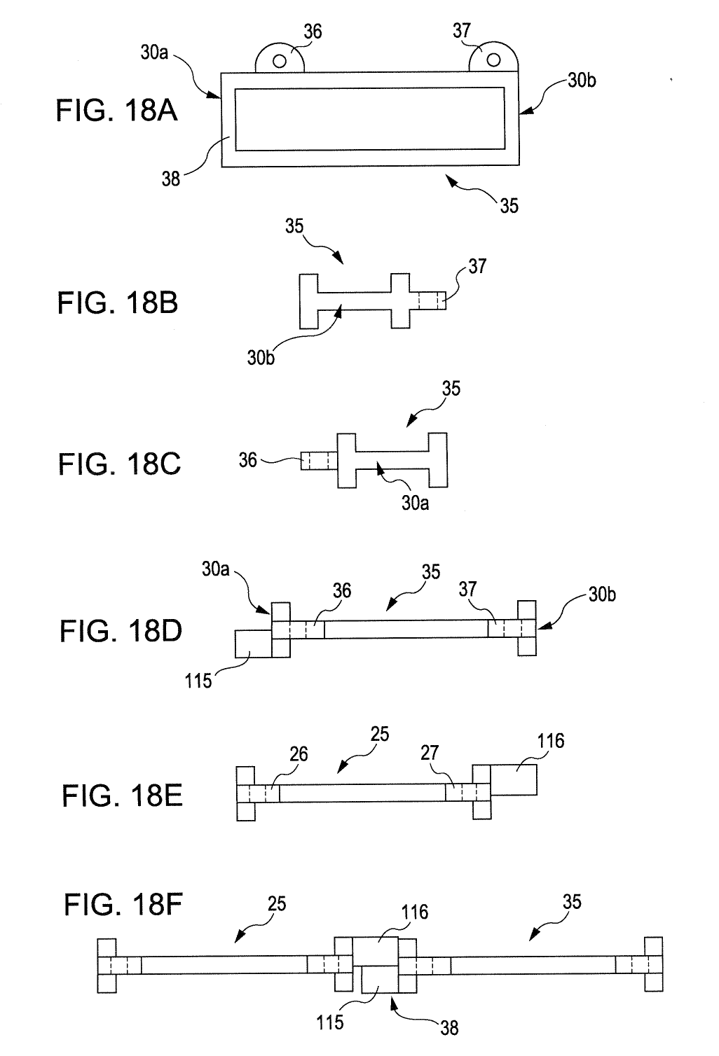

The overlapping portion 38 will now be described in detail with reference to FIGS. 18A to 18F. FIG. 18A shows the second water-blocking sheet 35 provided on the second key-top unit 5 seen from the bottom of the second key-top unit 5. FIG. 18B shows the second water-blocking sheet 35 seen from the right side of the second key-top unit 5. FIG. 18C shows the second water-blocking sheet 35 seen from the left side of the second key-top unit 5. FIG. 18D shows the second water-blocking sheet 35 seen from the side of the securing tabs 36 and 37. FIG. 18E shows the first water-blocking sheet 25 provided on the first key-top unit 4 seen from the side of the securing tabs 26 and 27. FIG. 18F shows the first and second water-blocking sheets 25 and 35 seen from the side of the securing tabs 26, 27, 36, and 37 with portions thereof overlapping each other.

As can be seen from FIGS. 18B to 18D, the second water-blocking sheet 35 has H-shaped longitudinal and lateral sections. That is, the second water-blocking sheet 35 has peripheral edges thereof projecting upward and downward. Likewise, referring now to FIG. 18E, the first water-blocking sheet 25 has H-shaped longitudinal and lateral sections.

Referring to FIG. 18D, the overlapping portion 38 of the second water-blocking sheet 35, i.e., the portion of the second water-blocking sheet 35 that overlaps the first water-blocking sheet 25, forms a tongue 115 projecting from a lower position of the second water-blocking sheet 35 in the direction opposite the direction in which the second water-blocking sheet 35 extends. Referring now to FIG. 18E, the portion of the first water-blocking sheet 25 that overlaps the second water-blocking sheet 35 forms a tongue 116 projecting from an upper position of the first water-blocking sheet 25 in the direction opposite the direction in which the first water-blocking sheet 25 extends.

When the first and second water-blocking sheets 25 and 35 overlap each other, referring now to FIG. 18F, the tongue 116 projecting from the upper position of the first water-blocking sheet 25 in the above-described direction is placed on the tongue 115 projecting from the lower position of the second water-blocking sheet 35 in the above-described direction. Thus, the water-blocking sheets 25 and 35 overlap each other at the overlapping portion 38.

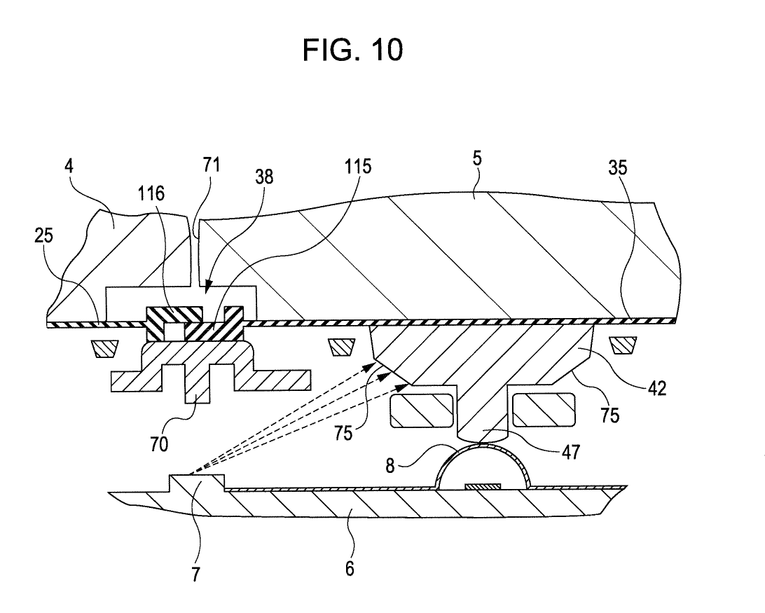

FIG. 10 is an enlarged sectional view of the overlapping portion 38 and relevant parts. As can be seen from FIG. 10, when the frame 10 is placed inside the casing formed by the front casing 1 and the rear casing 2, the pressing portion 70, having a convex shape, provided on the frame 10 comes into contact with the overlapping portion 38 where the key-top units 4 and 5 fitted to the front casing 1 overlap each other, thereby pressing the overlapping portion 38.

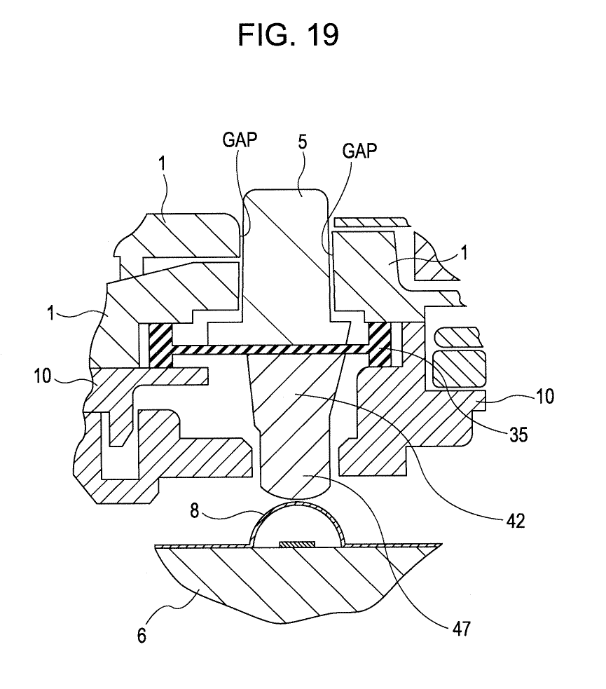

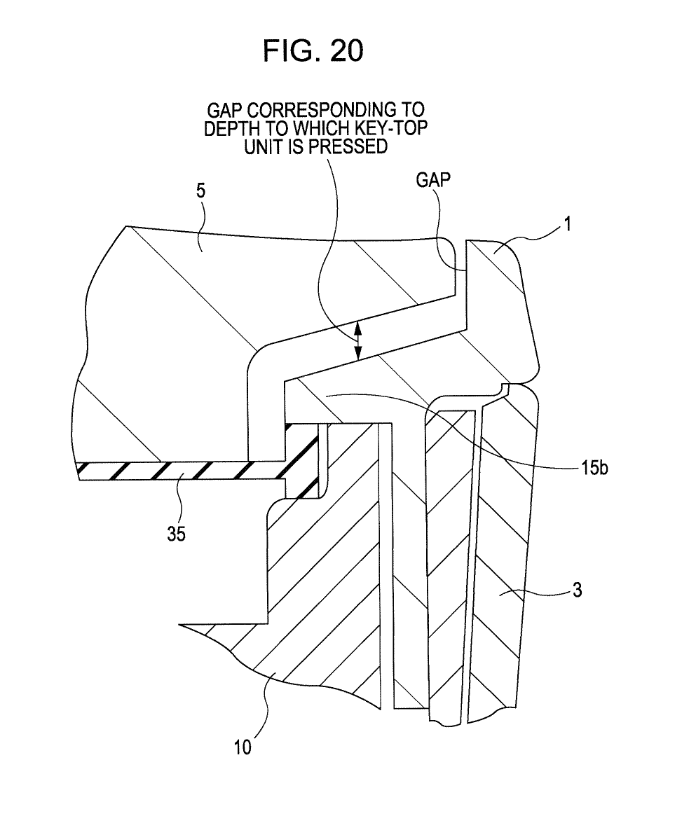

FIG. 19 is a sectional view of the mobile phone taken in the longitudinal direction thereof, showing relevant parts including the second key-top unit 5. FIG. 20 is a sectional view of the mobile phone taken in the lateral direction thereof, showing relevant parts including the second key-top unit 5. As can be seen from FIGS. 19 and 20, since the second water-blocking sheet 35 provided on the second key-top unit 5 has the H-shaped longitudinal and lateral sections with the peripheral edges thereof projecting upward and downward as described above, the edges projecting upward are in close contact with the front casing 1, and the edges projecting downward are in close contact with the frame 10. Likewise, the peripheral edges of the first water-blocking sheet 25 provided on the first key-top unit 4 are in close contact with the front casing 1 and the frame 10.

In the state where the key-top units 4 and 5 are fitted in the opening 14 next to each other, a small gap 71 shown in FIG. 10 is produced between the key-top units 4 and 5, and other small gaps shown in FIGS. 19 and 20 are produced between the edge of the opening 14 and the peripheries of the key-top units 4 and 5. These gaps may allow water and dust to enter the interior of the casing. For easier recognition, the gap 71 in FIG. 10 and the gaps in FIGS. 19 and 20 are shown larger than actual scales.

In the mobile phone according to the embodiment, however, since the H-shaped edges of the water-blocking sheets 25 and 35 provided on the key-top units 4 and 5 are in close contact with the front casing 1 and the frame 10 in such a manner as to surround the key-top units 4 and 5, water and dust are prevented from entering the interior of the casing through the gaps between the edge of the opening 14 and the key-top units 4 and 5.

Furthermore, since the overlapping portion 38 where the tongue 116 of the first water-blocking sheet 25 and the tongue 115 of the second water-blocking sheet 35 overlap each other is provided at the position corresponding to the gap 71 between the key-top units 4 and 5, water and dust are prevented from entering the interior of the casing through the gap 71. Moreover, the convex-shaped pressing portion 70 on the frame 10 that is in contact with and pressed against the overlapping portion 38 enhances the prevention of entrance of water and dust into the interior of the casing through the gap 71.

In addition, elastic sealing members made of a rubber material or the like may be provided in the gaps produced between the extended portions 21 and 31 of the key-top units 4 and 5 and the respective strength-maintaining projections 15a and 15b of the front casing 1 when the key-top units 4 and 5 are fitted in the opening 14. This further enhances the prevention of entrance of water and dust into the interior of the casing through the gaps.

The convex-shaped pressing portion 70 provided between the first- and second-pusher-member-receiving portions 61 and 62 of the frame 10 according to the embodiment may alternatively be provided on the board 6 or the rear casing 2, for example. That is, the pressing portion 70 may be provided at any position on the casing, except the front casing 1, as long as the pressing portion 70 has a convex shape that presses the overlapping portion 38.

In the mobile phone described above, the key-top units 4 and 5 function as, for example, a general-menu-displaying key and an on-hook/off-hook phone key, respectively. When the second key-top unit 5 is pressed, referring to FIG. 10, the pressing force applied to the second key-top unit 5 is transmitted to the second pusher member 42; the second supporting portion 44 connecting the second pusher member 42 to the connecting bar 40 bends; and the second projection 47 presses the corresponding dome switch 8 on the board 6. Thus, an on-hook or off-hook phone operation is performed.

Likewise, when the first key-top unit 4 is pressed, the pressing force applied to the first key-top unit 4 is transmitted to the first pusher member 41; the first supporting portion 43 connecting the first pusher member 41 to the connecting bar 40 bends; and the first projection 46 presses the corresponding dome switch 8 on the board 6. Thus, the general menu of the mobile phone is made to appear or disappear.

Key tops are often decorated with coating, printing, and the like for improved appearances thereof. In addition to such decoration, key tops are often provided with icons, such as characters, numbers, and symbols, representing individual operations. Furthermore, to help operations in dark environment, key tops are in general made of a material capable of guiding light from LEDs provided on a board or the like housed in a casing. Thus, for each key top, a contrast of illumination is produced between the icon and the other part, providing sufficient viewability of the icon.

In a case, however, where there is a substantial distance in the thickness direction of a casing between a board, having LEDs and housed in the casing, and key tops, it is difficult to form pusher structures that realize direct turning on/off of dome switches provided on the board by using the key tops alone. Moreover, the illumination by the LEDs mounted on the board for illumination of the key tops may become unstable.

To solve such problems, the mobile phone according to the embodiment includes the pusher unit having a pusher function and a light-guiding function is fitted to the frame 10, as described above referring to FIG. 6.

Specifically, the first and second pusher members 41 and 42 of the pusher unit shown in FIG. 6 have bearing surfaces 41a and 42a that receive the key-top units 4 and 5, respectively. Thus, the pusher unit provides a pusher structure that transmits pressing forces applied to the key-top units 4 and 5 to the dome switches 8 through the first and second projections 46 and 47, respectively.

In the pusher structure, the first and second supporting portions 43 and 44 are connected to the connecting bar 40 in a so-called cantilever manner. This allows the first and second supporting portions 43 and 44 to bend when the key-top units 4 and 5 are pressed, respectively. Thus, the pressing forces are transmitted to the dome switches 8, realizing on/off operations of the dome switches 8.

In addition, the pusher unit is made of a transparent or translucent material suitable for guiding light, and has bevels 75, shown in FIG. 10, angled at specific degrees so as to guide and diffuse light from the LEDs 7 toward the key-top units 4 and 5. Therefore, the light from the LEDs 7 is evenly and stably guided and diffused toward the key-top units 4 and 5.

With the pusher unit having a pusher function and a light-guiding function and fitted to the frame 10, the mobile phone according to the embodiment provides a pusher structure that realizes direct turning on/off of the dome switches 8 on the board 6 even if there is a substantial distance in the thickness direction of the casing between the board 6, having the LEDs 7 and housed in the casing, and the key-top units 4 and 5. Furthermore, the mobile phone according to the embodiment realizes a light-guiding function of evenly and stably guiding and diffusing the light from the LEDs 7 on the board 6 toward the key-top units 4 and 5.

### Advantageous Effects of the Embodiment

As is obvious from the above description, the mobile phone according to the embodiment provides the following advantageous effects.

1. With a resin connecting structure including the extended portions 21 and 31 of the first and second key-top units 4 and 5 and the pair of strength-maintaining projections 15a and 15b at the ends 1a and 1b of the front casing 1 defining the opening 14, a sufficient structural base and strength of the casing are provided.

2. If an integral structure in which the first and second key-top units 4 and 5 are bonded to a single water-blocking sheet is employed, it is difficult to fit the key-top units 4 and 5 into the front casing 1 from the back of the front casing 1 because the key-top units 4 and 5 interfere with the strength-maintaining projections 15a and 15b, respectively. In the mobile phone according to the embodiment, however, the key-top units 4 and 5 are separate components, and it is therefore easy to fit the key-top units 4 and 5 into the opening 14 of the front casing 1 having the strength-maintaining projections 15a and 15b.

3. The substantial distance in the thickness direction of the casing between the key-top units 4 and 5 and the dome switches 8 on the board 6 makes it difficult to provide sufficient waterproofness and dustproofness by using the key-top units 4 and 5 alone. In the mobile phone according to the embodiment, however, when the mobile phone is assembled by fitting the key-top units 4 and 5 into the opening 14, the edges (the upward and downward projections forming the H-shaped sections) of the water-blocking sheets 25 and 35 provided on the respective key-top units 4 and 5 come into close contact with the front casing 1 and the frame 10. This forms a closed sealing structure. Thus, water and dust are prevented from entering the interior of the casing through the gap between the edge of the opening 14 and the key-top units 4 and 5, whereby sufficient waterproofness and dustproofness are provided.

4. With the overlapping portion 38 formed by the tongue 115 of the second water-blocking sheet 35 that overlaps the tongue 116 of the first water-blocking sheet 25 at the position corresponding to the gap 71 between the key-top units 4 and 5, water and dust are prevented from entering the interior of the casing through the gap 71 between the key-top units 4 and 5. Moreover, the convex-shaped pressing portion 70 of the frame 10 that is in contact with and presses the overlapping portion 38 enhances the prevention of entrance of water and dust into the interior of the casing through the gap 71.

5. With the substantial distance in the thickness direction of the casing between the key-top units 4 and 5 and the dome switches 8 on the board 6, it is difficult to realize direct on/off operations of the dome switches 8 on the board 6 and to guide the light from the LEDs 7 by using the key-top units 4 and 5 alone. In the mobile phone according to the embodiment, however, a pusher structure and a light-guiding structure are realized with a single component, i.e., the pusher unit having a pusher function and a light-guiding function and fitted to the frame 10. Therefore, the mobile phone can be provided with low cost without any special substrate or flexible board for compensating the distance between the key-top units 4 and 5 and the dome switches 8 on the board 6.

6. The lengths of the key-top units 4 and 5 can be increased in the lateral direction of the casing while the tactile clicking sensation and the illuminating function of related-art button keys are maintained. Thus, the key-top units 4 and 5 can be pressed more easily. Furthermore, the outlines of the key-top units 4 and 5 match the outline of the touch panel module 13 provided on the front casing 1, producing continuity therebetween. Thus, the value of the mobile phone in terms of design is increased.

### Variation of the Embodiment

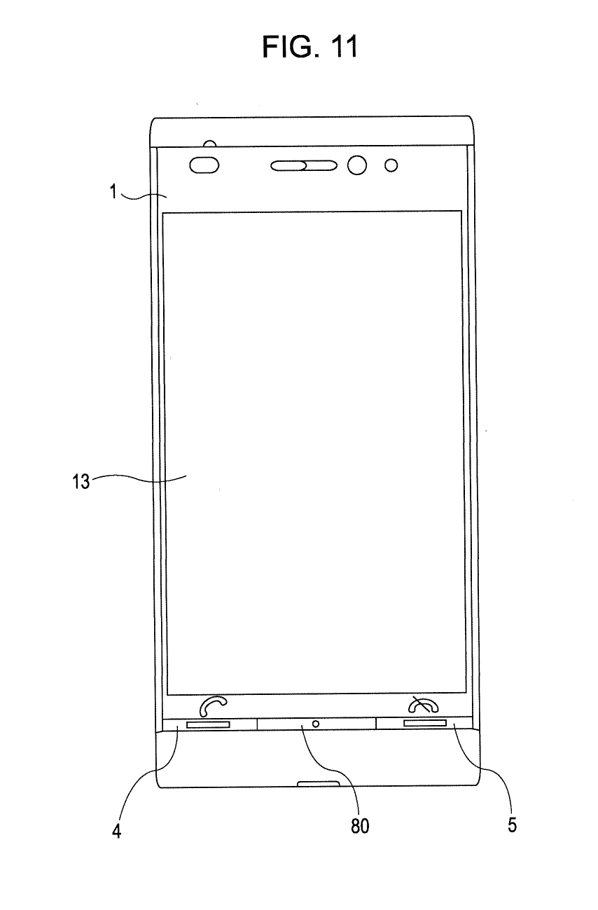

A variation of the mobile phone according to the above embodiment will now be described. While the mobile phone according to the above embodiment has two key-top units in total, specifically, the first key-top unit 4 and the second key-top unit 5, a mobile phone according to the following variation has three or more key-top units. The number of key-top units to be provided is at least three and may be more. The following variation concerns a case where three key-top units in total, specifically, the first and second key-top units 4 and 5 with an intermediate key-top unit 80 interposed therebetween as shown in FIG. 11.

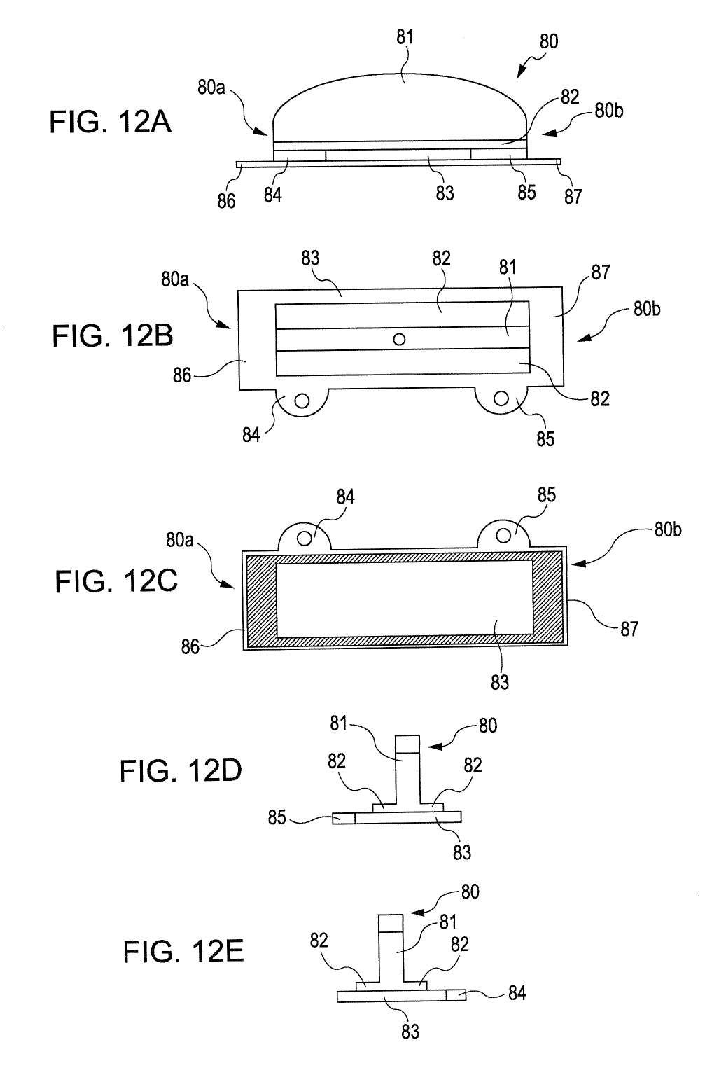

FIGS. 12A to 12E are a front view, a top view, a bottom view, a right-side view, and a left-side view, respectively, of the intermediate key-top unit 80 included in the mobile phone according to the variation. As can be seen from FIGS. 12A to 12E, the intermediate key-top unit 80 includes a projecting section 81 that is to project from the opening 14 when the intermediate key-top unit 80 is fitted into the opening 14. The intermediate key-top unit 80 also includes flanges 82 projecting in opposite directions that are orthogonal to the longitudinal direction of the opening 14 so that the intermediate key-top unit 80 does not come off from the opening 14 when the projecting section 81 is made to project from the opening 14.

Since the intermediate key-top unit 80 is interposed between the first and second key-top units 4 and 5, ends 80a and 80b thereof are cut vertically in the direction in which the projecting section 81 projects so as not to produce gaps with respect to the end 20b of the first key-top unit 4 and the end 30a of the second key-top unit 5.

The intermediate key-top unit 80 is provided on the bottom thereof, i.e., a surface thereof opposite the projecting section 81, with an intermediate water-blocking sheet 83 bonded thereto. The intermediate water-blocking sheet 83 has a larger area than the bottom surface of the intermediate key-top unit 80, and is made of a waterproof rubber material or the like processed into a substantially rectangular shape with a pair of securing tabs 84 and 85 at which the intermediate water-blocking sheet 83 is secured to the front casing 1 together with the intermediate key-top unit 80.

As in the cases of the first and second key-top units 4 and 5 described above referring to FIGS. 18A to 18F, the intermediate water-blocking sheet 83 has H-shaped sections with peripheral edges thereof projecting upward and downward. Therefore, when the mobile phone is assembled, the edges of the intermediate water-blocking sheet 83 come into close contact with the front casing 1 and the frame 10. Thus, water and dust are prevented from entering the interior of the casing through gaps between the intermediate key-top unit 80 and the key-top units 4 and 5 and between the intermediate key-top unit 80 and the edge of the opening 14.

Furthermore, as shown in FIG. 12C, the intermediate water-blocking sheet 83 has shading treatment done with, for example, black ink along the periphery thereof. With the shading treatment, light from a corresponding one of the LEDs 7 is efficiently guided toward the intermediate key-top unit 80.

Furthermore, the intermediate water-blocking sheet 83 has overlapping portions 86 and 87 that overlap a portion of the first water-blocking sheet 25 and a portion of the second water-blocking sheet 35, respectively, when the intermediate key-top unit 80 is fitted into the opening 14 together with the first and second key-top units 4 and 5.

In the mobile phone according to the embodiment described above, the overlapping portion 38 is provided on the second key-top unit 5. Instead of the overlapping portion 38 provided on the second key-top unit 5, the intermediate key-top unit 80 included in the mobile phone according to the variation has the overlapping portions 86 and 87 that overlap a portion of the first water-blocking sheet 25 and a portion of the second water-blocking sheet 35, respectively.

The intermediate key-top unit 80 is shaped such that, in the longitudinal direction of the opening 14, the sum of the lengths of the first, second, and intermediate key-top units 4, 5, and 80 becomes substantially the same as the length of the opening 14.

In this variation, the first, second, and intermediate key-top units 4, 5, and 80 function as, for example, an off-hook key, an on-hook key, and a general-menu-displaying key, respectively. The first and second key-top units 4 and 5 have substantially the same length. The intermediate key-top unit 80 provided between the key-top units 4 and 5 is a little longer than the key-top units 4 and 5.

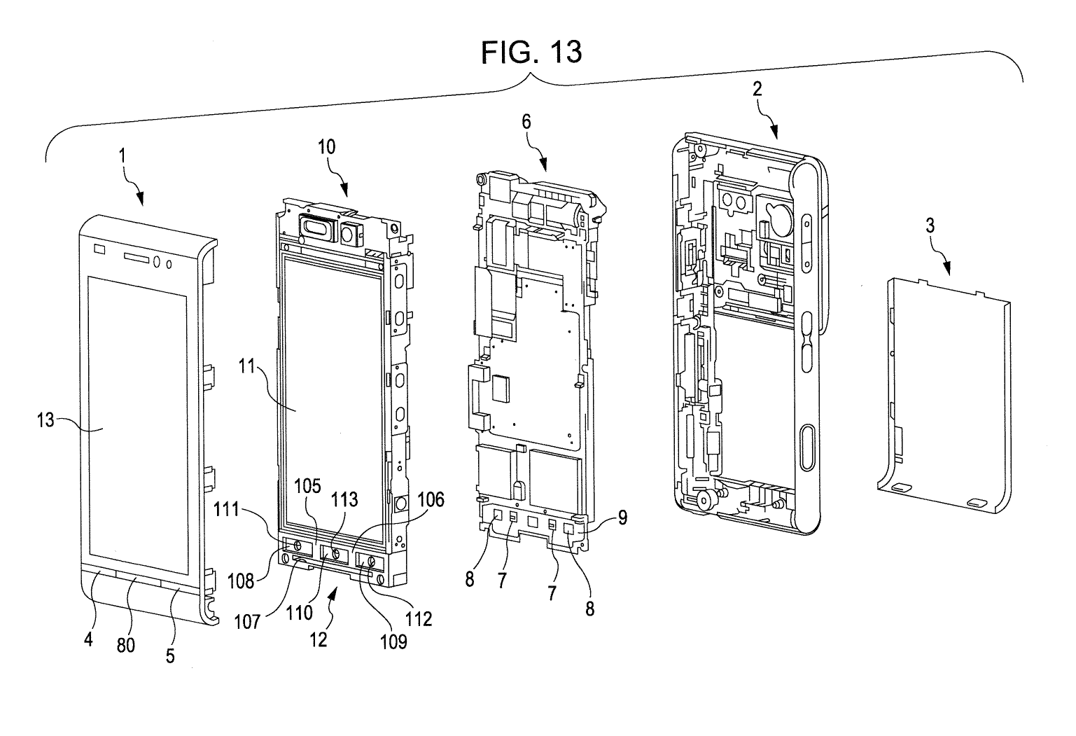

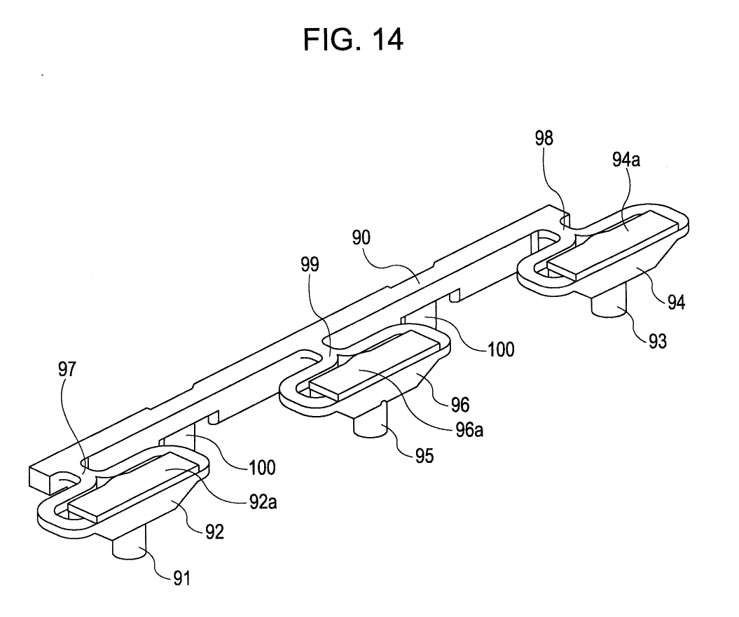

In the mobile phone according to the variation, a pusher unit to be mounted on the pusher-unit mount 12 provided on the frame 10 shown in FIG. 13 includes, referring now to FIG. 14, a connecting bar 90 having a substantially stick-like shape, a first pusher member 92, and a second pusher member 94. The first pusher member 92 has a first projection 91 and is to be positioned between the first key-top unit 4 and the dome switch 8 corresponding thereto. When the first key-top unit 4 is pressed, the pressing force is transmitted to the dome switch 8 through the first projection 91. The second pusher member 94 has a second projection 93 and is to be positioned between the second key-top unit 5 and the dome switch 8 corresponding thereto. When the second key-top unit 5 is pressed, the pressing force is transmitted to the dome switch 8 through the second projection 93.

In the mobile phone according to the variation, the pusher unit also includes an intermediate pusher member 96 having an intermediate projection 95. The intermediate pusher member 96 is to be positioned between the intermediate key-top unit 80 and the dome switch 8 corresponding thereto. When the intermediate key-top unit 80 is pressed, the pressing force is transmitted to the dome switch 8 through the intermediate projection 95.

The pusher unit also includes a first supporting portion 97, a second supporting portion 98, an intermediate supporting portion 99, and a pair of locking hooks 100. The first supporting portion 97 connects the first pusher member 92 to the connecting bar 90 and bends in response to the pressing of the first key-top unit 4. The second supporting portion 98 connects the second pusher member 94 to the connecting bar 90 and bends in response to the pressing of the second key-top unit 5. The intermediate supporting portion 99 connects the intermediate pusher member 96 to the connecting bar 90 and bends in response to the pressing of the intermediate key-top unit 80. The locking hooks 100 are provided on the connecting bar 90 and secure the pusher unit to the frame 10.

The pusher unit is formed such that the connecting bar 90, the first pusher member 92, the first supporting portion 97, the second pusher member 94, the second supporting portion 98, the intermediate pusher member 96, and the intermediate supporting portion 99 are integrally molded from, for example, a transparent or translucent light-conducting material, such as polycarbonate resin, that bends when a force is applied thereto and restores the original shape when the applied force is removed.

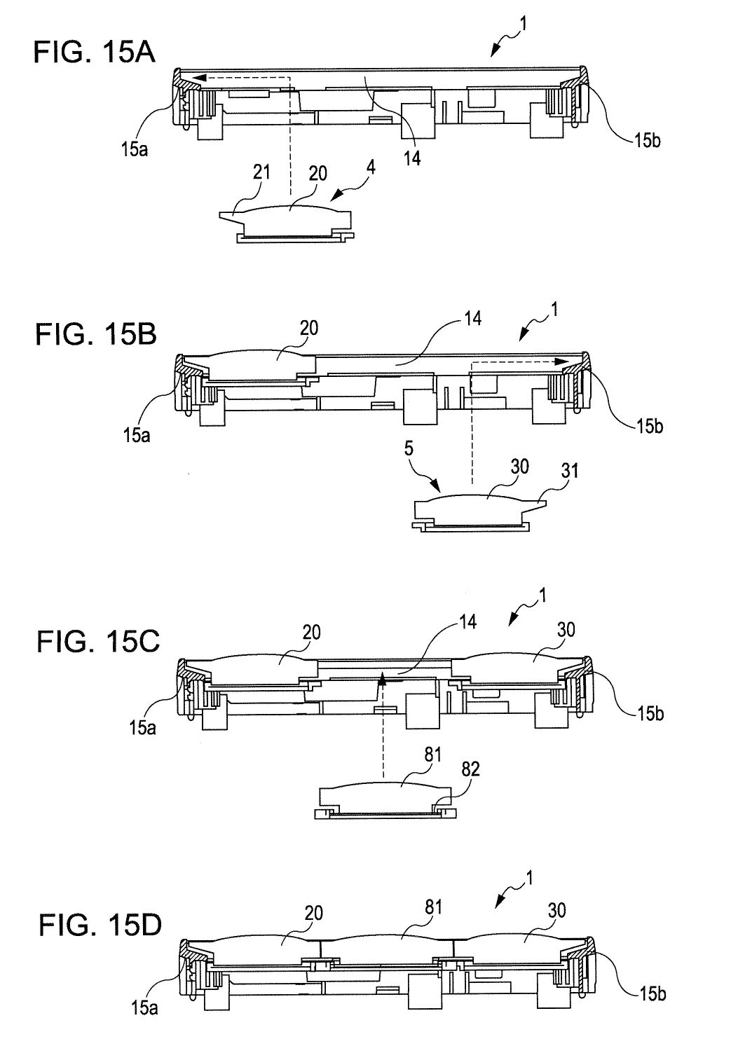

FIGS. 15A to 15D show a process of fitting the key-top units 4, 5, and 80 to the front casing 1. FIGS. 15A to 15D are sectional views of the front casing 1 taken along the opening 14.

To fit the first key-top unit 4 to the front casing 1, referring to FIG. 15A, the projecting section 20 of the first key-top unit 4 is inserted into the opening 14 from the back of the front casing 1. Thus, the projecting section 20 of the first key-top unit 4 projects from the opening 14, with the flanges 22 of the first key-top unit 4 being caught at the opening 14. In this state, the first key-top unit 4 is slid toward the strength-maintaining projection 15a of the front casing 1 so that the extended portion 21 of the first key-top unit 4 is positioned above the strength-maintaining projection 15a.

Subsequently, referring to FIG. 15B, the projecting section 30 of the second key-top unit 5 is inserted into the opening 14 from the back of the front casing 1. Thus, the projecting section 30 of the second key-top unit 5 projects from the opening 14, with the flanges 32 of the second key-top unit 5 being caught at the opening 14. In this state, the second key-top unit 5 is slid toward the strength-maintaining projection 15b of the front casing 1 so that the extended portion 31 of the second key-top unit 5 is positioned above the strength-maintaining projection 15b.

Subsequently, referring to FIG. 15C, the projecting section 81 of the intermediate key-top unit 80 is inserted into a space in the opening 14 between the first and second key-top units 4 and 5 from the back of the front casing 1. Thus, the projecting section 81 of the intermediate key-top unit 80 projects from the opening 14, with the flanges 82 of the intermediate key-top unit 80 being caught at the opening 14. In this manner, as shown in FIG. 15D, the intermediate key-top unit 80 is interposed between the first and second key-top units 4 and 5.

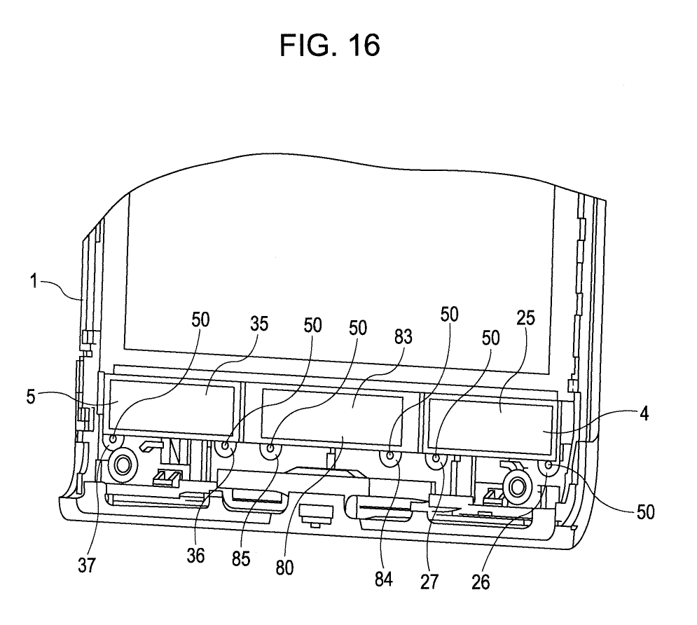

When the first key-top unit 4 is slid toward the strength-maintaining projection 15a of the front casing 1 such that the extended portion 21 of the first key-top unit 4 is positioned above the strength-maintaining projection 15a; the second key-top unit 5 is then slid toward the strength-maintaining projection 15b of the front casing 1 such that the extended portion 31 of the second key-top unit 5 is positioned above the strength-maintaining projection 15b ; and the intermediate key-top unit 80 is then interposed between the key-top units 4 and 5, referring now to FIG. 16, the pair of securing tabs 26 and 27 of the first water-blocking sheet 25, the pair of securing tabs 36 and 37 of the second water-blocking sheet 35, and the pair of securing tabs 84 and 85 of the intermediate water-blocking sheet 83 engage with projections 50, respectively, provided on the front casing 1. Thus, the key-top units 4, 5, and 80 are secured to the front casing 1 at the opening 14.

The opening 14 of the front casing 1 is provided by linearly and continuously cutting the front casing 1 from a position near the end 1a to a position near the end 1b of the front casing 1. Furthermore, the ends 1a and 1b of the front casing 1 that define the opening 14 are reinforced with the pair of strength-maintaining projections 15a and 15b.

Therefore, the opening 14 can be widened to extend from a position near the end 1a to a position near the end 1b of the front casing 1 while sufficient strength is provided to the ends 1a and 1b of the front casing 1 that define the opening 14. Consequently, the outside dimensions of the key-top units 4, 5, and 80 to be provided in the opening 14 can be increased. In particular, the outside dimensions of the first and second key-top units 4 and 5 to be positioned on both sides of the front casing 1 can be maximized such that the key-top units 4 and 5 reach near the ends 1a and 1b of the front casing 1.

In the mobile phone according to the variation, the allowance for such increase in the outside dimensions of the key-top units 4, 5, and 80 contributes to the flexible designs of the key-top units 4, 5, and 80 and the casing.

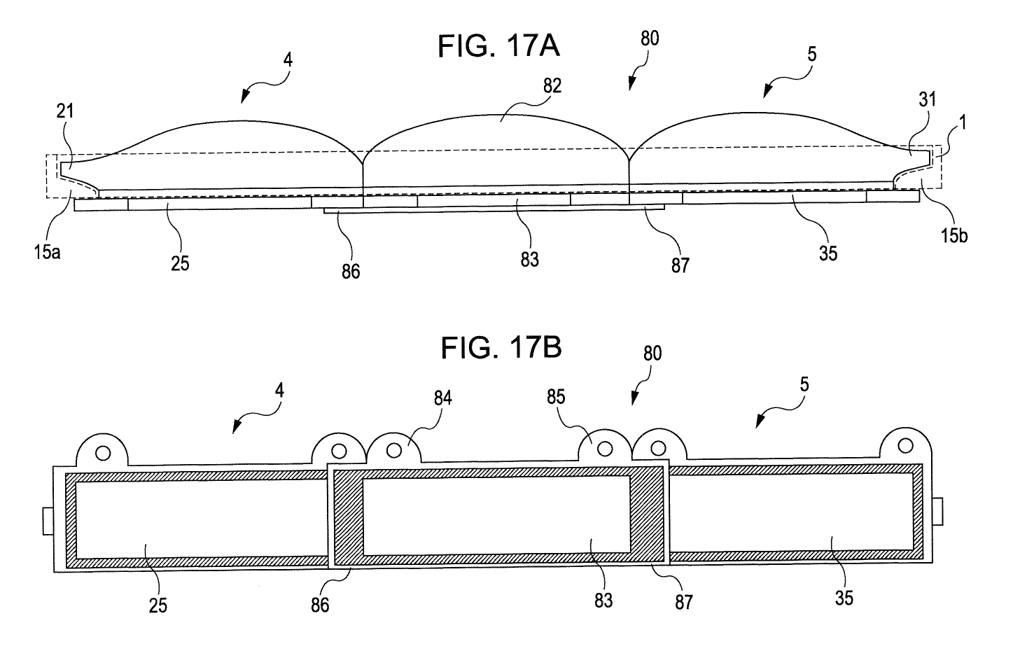

FIG. 17A is a side view of the key-top units 4, 5, and 80 fitted in the opening 14 of the front casing 1. FIG. 17B is a bottom view of the key-top units 4, 5, and 80 fitted in the opening 14 of the front casing 1. As can be seen from FIGS. 17A and 17B, when the key-top units 4, 5, and 80 are fitted in the opening 14 of the front casing 1, the overlapping portions 86 and 87 of the intermediate water-blocking sheet 83 provided on the intermediate key-top unit 80 overlap a portion of the first water-blocking sheet 25 provided on the first key-top unit 4 and a portion of the second water-blocking sheet 35 provided on the second key-top unit 5, respectively. Pressing portions 105 and 106, shown in FIG. 13 and described below, provided on the frame 10 come into contact with the overlapping portions 86 and 87, respectively.

A process of mounting the pusher unit onto the frame 10 will now be described. Referring to FIG. 13, the frame 10 has the pusher-unit mount 12 including a groove 107 that receives the connecting bar 90 of the pusher unit, described above referring to FIG. 14, a concave-shaped first-pusher-member-receiving portion 108 that receives the first pusher member 92, a concave-shaped second-pusher-member-receiving portion 109 that receives the second pusher member 94, and a concave-shaped intermediate-pusher-member-receiving portion 110 that receives the intermediate pusher member 96.

The first-pusher-member-receiving portion 108 has a hole 111 into which the first projection 91 of the first pusher member 92 is to be inserted. The second-pusher-member-receiving portion 109 has a hole 112 into which the second projection 93 of the second pusher member 94 is to be inserted. The intermediate-pusher-member-receiving portion 110 has a hole 113 into which the intermediate projection 95 of the intermediate pusher member 96 is to be inserted.

The groove 107 is provided with locking holes (not shown) to which the pair of locking hooks 100 of the pusher unit shown in FIG. 14 are to be hooked, respectively.

To mount the pusher unit onto the pusher-unit mount 12, the connecting bar 90 of the pusher unit is fitted into the groove 107, the first projection 91 of the first pusher member 92 is then inserted into the hole 111 of the first-pusher-member-receiving portion 108, and the first pusher member 92 is then fitted into the first-pusher-member-receiving portion 108. Meanwhile, the second projection 93 of the second pusher member 94 is inserted into the hole 112 of the second-pusher-member-receiving portion 109, and the second pusher member 94 is then fitted into the second-pusher-member-receiving portion 109. Furthermore, the intermediate projection 95 of the intermediate pusher member 96 is inserted into the hole 113 of the intermediate-pusher-member-receiving portion 110, and the intermediate pusher member 96 is then fitted into the intermediate-pusher-member-receiving portion 110.

Thus, the pair of locking hooks 100 shown in FIG. 14 are hooked into the locking holes provided in the groove 107. Consequently, the pusher unit is secured to the pusher-unit mount 12 of the frame 10.

To assemble the mobile phone, with the key-top units 4, 5, and 80 fitted to the front casing 1 and the pusher unit mounted on the pusher-unit mount 12 of the frame 10, as described above, the frame 10 and the board 6 are housed together in the casing formed by the front casing 1 and the rear casing 2, shown in FIG. 13, and the back cover 3 is then put to the rear casing 2. Thus, the mobile phone according to the variation is assembled.

As shown in FIG. 13, a portion of the frame 10 between the first-pusher-member-receiving portion 108 and the intermediate-pusher-member-receiving portion 110 forms the pressing portion 105, which has a convex shape. Furthermore, a portion of the frame 10 between the second-pusher-member-receiving portion 109 and the intermediate-pusher-member-receiving portion 110 forms the pressing portion 106, which has a convex shape. When the frame 10 is placed inside the casing formed by the front casing 1 and the rear casing 2, the pressing portions 105 and 106 come into contact with the overlapping portions 86 and 87, respectively, of the intermediate water-blocking sheet 83 provided on the intermediate key-top unit 80 fitted to the front casing 1, thereby pressing the overlapping portions 86 and 87 with specific pressures.

The water-blocking sheets 25, 35, and 83 provided on the respective key-top units 4, 5, and 80 each have the peripheral edges thereof projecting upward and downward, as described above, thereby having H-shaped longitudinal and lateral sections. Therefore, as described above referring to FIGS. 19 and 20, the water-blocking sheets 25, 35, and 83 come into close contact with the front casing 1 at the edges thereof projecting upward and with the frame 10 at the edges thereof projecting downward.

In the state where the key-top units 4, 5, and 80 are fitted in the opening 14 next to one another, small gaps 71 shown in FIG. 10 are produced between the key-top units 4 and 80 and between the key-top units 5 and 80, and other small gaps shown in FIGS. 19 and 20 are produced between the edge of the opening 14 and the peripheries of the key-top units 4, 5, and 80. These gaps may allow water and dust to enter the interior of the casing.

In the mobile phone according to the variation of the embodiment, however, since the H-shaped edges of the water-blocking sheets 25, 35, and 83 provided on the key-top units 4, 5, and 80 are in close contact with the front casing 1 and the frame 10 in such a manner as to surround the key-top units 4, 5, and 80, respectively, water and dust are prevented from entering the interior of the casing through the gap between the edge of the opening 14 and the key-top units 4, 5, and 80.

Furthermore, since the overlapping portions 86 and 87 where the intermediate water-blocking sheet 83 provided on the intermediate key-top unit 80 overlap the water-blocking sheets 25 and 35 of the key-top units 4 and 5 at the positions corresponding to the gaps 71 between the intermediate key-top unit 80 and the key-top units 4 and 5, water and dust are prevented from entering the interior of the casing through the gaps 71. Moreover, the convex-shaped pressing portions 105 and 106 of the frame 10 that are in contact with and pressed against the overlapping portions 86 and 87 enhance the prevention of entrance of water and dust into the interior of the casing through the gaps 71.

In addition, elastic sealing members made of a rubber material or the like may be provided in the gaps provided between the extended portions 21 and 31 of the key-top units 4 and 5 and the respective strength-maintaining projections 15a and 15b of the front casing 1 when the key-top units 4 and 5 are fitted in the opening 14. This further enhances the prevention of entrance of water and dust into the interior of the casing through the gaps.

The convex-shaped pressing portions 105 and 106 provided between the first- and intermediate-pusher-member-receiving portions 108 and 110 and between the second- and intermediate-pusher-member-receiving portions 109 and 110, respectively, of the frame 10 according to the variation may alternatively be provided on the board 6 or the rear casing 2, for example. That is, the pressing portions 105 and 106 may be provided at any position on the casing, except the front casing 1, as long as the pressing portions 105 and 106 have convex shapes that press the overlapping portions 86 and 87, respectively.

In the mobile phone according to the variation, the key-top units 4, 5, and 80 function as, for example, an off-hook phone key, an on-hook phone key, and a general-menu-displaying key, respectively. When the first key-top unit 4 is pressed, referring to FIG. 10, the pressing force applied to the first key-top unit 4 is transmitted to the first pusher member 92; the first supporting portion 97 connecting the first pusher member 92 to the connecting bar 90 bends; and the first projection 91 presses the corresponding dome switch 8 on the board 6. Thus, an off-hook phone operation is performed.

When the second key-top unit 5 is pressed, referring also to FIG. 10, the pressing force applied to the second key-top unit 5 is transmitted to the second pusher member 94; the second supporting portion 98 connecting the second pusher member 94 to the connecting bar 90 bends; and the second projection 93 presses the corresponding dome switch 8 on the board 6. Thus, an on-hook phone operation is performed.

When the intermediate key-top unit 80 is pressed, referring also to FIG. 10, the pressing force applied to the intermediate key-top unit 80 is transmitted to the intermediate pusher member 96; the intermediate supporting portion 99 connecting the intermediate pusher member 96 to the connecting bar 90 bends; and the intermediate projection 95 presses the corresponding dome switch 8 on the board 6. Thus, the general menu of the mobile phone is made to appear or disappear.

Key tops are often decorated with coating, printing, and the like for improved appearances thereof. In addition to such decoration, key tops are often provided with icons, such as characters, numbers, and symbols, representing individual operations. Furthermore, to help operations in dark environment, key tops are in general made of a material capable of guiding light from LEDs provided on a board or the like housed in a casing. Thus, for each key top, a contrast of illumination is produced between the icon and the other part, providing sufficient viewability of the icon.

In a case, however, where there is a substantial distance in the thickness direction of a casing between a board, having LEDs and housed in the casing, and key tops, it is difficult to form pusher structures that realize direct turning on/off of the dome switches on the board by using the key tops alone. Moreover, the illumination by the LEDs mounted on the board for illumination of the key tops may become unstable.

To solve such problems, the mobile phone according to the variation of the embodiment includes the pusher unit having a pusher function and a light-guiding function is fitted to the frame 10, as described above referring to FIG. 14.

Specifically, the first, second, and intermediate pusher members 92, 94, and 96 of the pusher unit shown in FIG. 14 have bearing surfaces 92a, 94a, and 96a that receive the key-top units 4, 5, and 80, respectively. Thus, the pusher unit provides a pusher structure that transmits pressing forces applied to the key-top units 4, 5, and 80 to the dome switches 8 through the first, second, and intermediate projections 91, 93, and 95, respectively.

In the pusher structure, the first, second, and intermediate supporting portions 97, 98, and 99 are connected to the connecting bar 90 in a so-called cantilever manner. This allows the first, second, and intermediate supporting portions 97, 98, and 99 to bend when the key-top units 4, 5, and 80 are pressed, respectively. Thus, the pressing forces are transmitted to the dome switches 8, realizing on/off operations of the dome switches 8.

In addition, the pusher unit is made of a transparent or translucent material suitable for guiding light, and has bevels 75, shown in FIG. 10, angled at specific degrees so as to guide and diffuse light from the LEDs 7 toward the key-top units 4, 5, and 80. Therefore, the light from the LEDs 7 is evenly and stably guided and diffused toward the key-top units 4, 5, and 80.

With the pusher unit having a pusher function and a light-guiding function and fitted to the frame 10, the mobile phone according to the variation of the embodiment provides a pusher structure that realizes direct turning on/off of the dome switches 8 on the board 6 even if there is a substantial distance in the thickness direction of the casing between the board 6, having the LEDs 7 and housed in the casing, and the key-top units 4, 5, and 80. Furthermore, the mobile phone according to the variation realizes a light-guiding function of evenly and stably guiding and diffusing the light from the LEDs 7 on the board 6 toward the key-top units 4, 5, and 80.

### Advantageous Effects of the Variation of the Embodiment

As is obvious from the above description, the mobile phone according to the variation of the embodiment provides the following advantageous effects.

1. With a resin connecting structure including the extended portions 21 and 31 of the first and second key-top units 4 and 5 and the pair of strength-maintaining projections 15a and 15b at the ends 1a and 1b of the front casing 1 defining the opening 14, a sufficient structural base and strength of the casing are provided.

2. If an integral structure in which the first, second, and intermediate key-top units 4, 5, and 80 are bonded to a single water-blocking sheet is employed, it is difficult to fit the key-top units 4, 5, and 80 into the front casing 1 from the back of the front casing 1 because the extended portions 21 and 31 of the key-top units 4 and 5 interfere with the strength-maintaining projections 15a and 15b, respectively. In the mobile phone according to the variation of the embodiment, however, the key-top units 4, 5, and 80 are separate components, and it is therefore easy to fit the key-top units 4, 5, and 80 into the opening 14 of the front casing 1 having the strength-maintaining projections 15a and 15b.

3. The substantial distance in the thickness direction of the casing between the key-top units 4, 5, and 80 and the dome switches 8 on the board 6 makes it difficult to provide sufficient waterproofness and dustproofness by using the key-top units 4, 5, and 80 alone. In the mobile phone according to the variation of the embodiment, however, when the mobile phone is assembled by fitting the key-top units 4, 5, and 80 into the opening 14, the edges (the upward and downward projections forming the H-shaped sections) of the water-blocking sheets 25, 35, and 83 provided on the respective key-top units 4, 5, and 80 come into close contact with the front casing 1 and the frame 10. This forms a closed sealing structure. Thus, water and dust are prevented from entering the interior of the casing through the gap between the edge of the opening 14 and the key-top units 4, 5, and 80, whereby sufficient waterproofness and dustproofness are provided.

4. With the overlapping portions 86 and 87 where the intermediate water-blocking sheet 83 provided on the intermediate key-top unit 80 overlaps the first and second water-blocking sheets 25 and 35 of the first and second key-top units 4 and 5 at the position corresponding to the gaps 71 between the intermediate key-top unit 80 and the key-top units 4 and 5, water and dust are prevented from entering the interior of the casing through the gaps 71. Moreover, the convex-shaped pressing portions 105 and 106 of the frame 10 that are in contact with and press the overlapping portions 86 and 87 enhance the prevention of entrance of water and dust into the interior of the casing through the gaps 71.

5. With the substantial distance in the thickness direction of the casing between the key-top units 4, 5, and 80 and the dome switches 8 on the board 6, it is difficult to realize direct on/off operations of the dome switches 8 on the board 6 and to guide the light from the LEDs 7 by using the key-top units 4, 5, and 80 alone. In the mobile phone according to the variation of the embodiment, however, a pusher structure and a light-guiding structure are realized with a single component, i.e., the pusher unit having a pusher function and a light-guiding function and fitted to the frame 10. Therefore, the mobile phone can be provided with low cost without any special substrate or flexible board for compensating the distance between the key-top units 4, 5, and 80 and the dome switches 8 on the board 6.

6. The lengths of the key-top units 4, 5, and 80 can be increased in the lateral direction of the casing while the tactile clicking sensation and the illuminating function of related-art button keys are maintained. Thus, the key-top units 4, 5, and 80 can be pressed more easily. Furthermore, the outlines of the key-top units 4, 5, and 80 match the outline of the touch panel module 13 provided on the front casing 1, producing continuity therebetween. Thus, the value of the mobile phone in terms of design is increased.

### Other Variation

While the embodiment and the variation thereof described above concern the case where the present invention is applied to a mobile phone, the present invention may also be applied to other electronic apparatuses having press-to-operate button keys, such as PHSs, PDAs, portable game machines, digital cameras, moving-image-capturing apparatuses, and notebook and desktop personal computers. In any case, advantageous effects as in the embodiment and the variation are provided.

The present application contains subject matter related to that disclosed in Japanese Priority Patent Application JP 2009-223529 filed in the Japan Patent Office on Sep. 28, 2009, the entire content of which is hereby incorporated by reference.

Since the embodiment and the variation thereof described above are only examples of the present invention, the present invention is not limited thereto, and various modifications can be made thereto depending on design requirements and other factors insofar as they are within the technical scope of the present invention.

What is claimed is:

1. A button-key device comprising:
a casing having
an opening provided by linearly and continuously cutting the casing from a position near one end to a position near another end, and
a pair of strength-maintaining projections projecting in opposite directions from the ends, respectively, of the casing in a longitudinal direction of the opening;
a first key-top unit including
a projecting section projecting from the opening when the first key-top unit is fitted in the opening,
an extended portion provided by extending an end of the projecting section, the end facing one of the strength-maintaining projections when the first key-top unit is fitted in the opening, and
flanges projecting in opposite directions orthogonal to the longitudinal direction of the opening;
a second key-top unit including
a projecting section projecting from the opening when the second key-top unit is fitted in the opening,
an extended portion provided by extending an end of the projecting section, the end facing the other strength-maintaining projection when the second key-top unit is fitted in the opening, and
flanges projecting in opposite directions orthogonal to the longitudinal direction of the opening,
the second key-top unit being provided such that a sum of lengths of the first and second key-top units in the longitudinal direction of the opening becomes substantially the same as a longitudinal length of the opening;
a first water-blocking sheet provided on a bottom of the first key-top unit, the bottom being opposite the projecting section;
a second water-blocking sheet provided on a bottom of the second key-top unit, the bottom being opposite the projecting section, the second water-blocking sheet having an overlapping portion that overlaps a portion of the first water-blocking sheet when the first and second key-top units are fitted in the opening;
a pressing portion provided on the casing and applying a pressure to the overlapping portion by being in contact therewith;
switches provided on a board housed in the casing and in correspondence with the first and second key-top units;
a first pusher member provided between the first key-top unit and a corresponding one of the switches and configured to transmit to the switch a pressing force applied when the first key-top unit is pressed; and
a second pusher member provided between the second key-top unit and the other corresponding switch and configured to transmit to the switch a pressing force applied when the second key-top unit is pressed.

2. The button-key device according to claim 1, further comprising:
a connecting bar having a substantially stick-like shape;
a first supporting portion connecting the first pusher member to the connecting bar and configured to bend when the first key-top unit is pressed; and
a second supporting portion connecting the second pusher member to the connecting bar and configured to bend when the second key-top unit is pressed,
wherein the connecting bar, the first and second pusher members, and the first and second supporting portions are integrally molded from a material.

3. The button-key device according to claim 2, further comprising:
a light emitter,
wherein the connecting bar, the first and second pusher members, and the first and second supporting portions are integrally molded from a light-guiding material, and
wherein at least the first and second pusher members have bevels angled at specific degrees so as to guide light from the light emitter toward the first and second key-top units.

4. A button-key device comprising:
a casing having
an opening provided by linearly and continuously cutting the casing from a position near one end to a position near another end, and
a pair of strength-maintaining projections projecting in opposite directions from the ends, respectively, of the casing in a longitudinal direction of the opening;
a first key-top unit including
a projecting section projecting from the opening when the first key-top unit is fitted in the opening,
an extended portion provided by extending an end of the projecting section, the end facing one of the strength-maintaining projections when the first key-top unit is fitted in the opening, and
flanges projecting in opposite directions orthogonal to the longitudinal direction of the opening;
a second key-top unit including
a projecting section projecting from the opening when the second key-top unit is fitted in the opening,
an extended portion provided by extending an end of the projecting section, the end facing the other strength-maintaining projections when the second key-top unit is fitted in the opening, and
flanges projecting in opposite directions orthogonal to the longitudinal direction of the opening;
at least one intermediate key-top unit including
a projecting section projecting from the opening when the intermediate key-top unit is fitted in the opening, and
flanges projecting in opposite directions orthogonal to the longitudinal direction of the opening,
the intermediate key-top unit being provided such that a sum of lengths of the first, second, and intermediate key-top units in the longitudinal direction of the opening becomes substantially the same as a longitudinal length of the opening;
a first water-blocking sheet provided on a bottom of the first key-top unit, the bottom being opposite the projecting section;
a second water-blocking sheet provided on a bottom of the second key-top unit, the bottom being opposite the projecting section;
an intermediate water-blocking sheet provided on a bottom of the intermediate key-top unit, the bottom being opposite the projecting section, the intermediate water-blocking sheet having overlapping portions that overlap portions of some of the water-blocking sheets adjoining thereto when the first, second, and intermediate key-top units are fitted in the opening;
pressing portions provided on the casing and applying pressures to the overlapping portions by being in contact therewith;
switches provided on a board housed in the casing and in correspondence with the first, second, and intermediate key-top units;
a first pusher member provided between the first key-top unit and a corresponding one of the switches and configured to transmit to the switch a pressing force applied when the first key-top unit is pressed;
a second pusher member provided between the second key-top unit and another corresponding one of the switches and configured to transmit to the switch a pressing force applied when the second key-top unit is pressed; and
an intermediate pusher member provided between the intermediate key-top unit and the other corresponding switch and configured to transmit to the switch a pressing force applied when the intermediate key-top unit is pressed.

5. The button-key device according to claim 4, further comprising:
a connecting bar having a substantially stick-like shape;
a first supporting portion connecting the first pusher member to the connecting bar and configured to bend when the first key-top unit is pressed;
a second supporting portion connecting the second pusher member to the connecting bar and configured to bend when the second key-top unit is pressed; and
an intermediate supporting portion connecting the intermediate pusher member to the connecting bar and configured to bend when the intermediate key-top unit is pressed,
wherein the connecting bar; the first, second, and intermediate pusher members; and the first, second, and intermediate supporting portions are integrally molded from a material.

6. The button-key device according to claim 5, further comprising:
a light emitter,
wherein the connecting bar; the first, second, and intermediate pusher members; and the first, second, and intermediate supporting portions are integrally molded from a light-guiding material, and
wherein at least the first, second, and intermediate pusher members have bevels angled at specific degrees so as to guide light from the light emitter toward the first, second, and intermediate key-top units.

7. A portable terminal apparatus comprising:
a button-key device including
a casing having
an opening provided by linearly and continuously cutting the casing from a position near one end to a position near another end, and
a pair of strength-maintaining projections projecting in opposite directions from the ends, respectively, of the casing in a longitudinal direction of the opening;
a first key-top unit including
a projecting section projecting from the opening when the first key-top unit is fitted in the opening,
an extended portion provided by extending an end of the projecting section, the end facing one of the strength-maintaining projections when the first key-top unit is fitted in the opening, and
flanges projecting in opposite directions orthogonal to the longitudinal direction of the opening;
a second key-top unit including
a projecting section projecting from the opening when the second key-top unit is fitted in the opening,
an extended portion provided by extending an end of the projecting section, the end facing the other strength-maintaining projection when the second key-top unit is fitted in the opening, and
flanges projecting in opposite directions orthogonal to the longitudinal direction of the opening,
the second key-top unit being provided such that a sum of lengths of the first and second key-top units in the longitudinal direction of the opening becomes substantially the same as a longitudinal length of the opening;
a first water-blocking sheet provided on a bottom of the first key-top unit, the bottom being opposite the projecting section;
a second water-blocking sheet provided on a bottom of the second key-top unit, the bottom being opposite the projecting section, the second water-blocking sheet having an overlapping portion that overlaps a portion of the first water-blocking sheet when the first and second key-top units are fitted in the opening;
a pressing portion provided on the casing and applying a pressure to the overlapping portion by being in contact therewith;
switches provided on a board housed in the casing and in correspondence with the first and second key-top units;
a first pusher member provided between the first key-top unit and a corresponding one of the switches and configured to transmit to the switch a pressing force applied when the first key-top unit is pressed; and
a second pusher member provided between the second key-top unit and the other corresponding switch and configured to transmit to the switch a pressing force applied when the second key-top unit is pressed.

8. A portable terminal apparatus comprising:
a button-key device including
a casing having
an opening provided by linearly and continuously cutting the casing from a position near one end to a position near another end, and
a pair of strength-maintaining projections projecting in opposite directions from the ends, respectively, of the casing in a longitudinal direction of the opening;
a first key-top unit including
a projecting section projecting from the opening when the first key-top unit is fitted in the opening,
an extended portion provided by extending an end of the projecting section, the end facing one of the strength-maintaining projections when the first key-top unit is fitted in the opening, and
flanges projecting in opposite directions orthogonal to the longitudinal direction of the opening;
a second key-top unit including
a projecting section projecting from the opening when the second key-top unit is fitted in the opening,
an extended portion provided by extending an end of the projecting section, the end facing the other strength-maintaining projections when the second key-top unit is fitted in the opening, and
flanges projecting in opposite directions orthogonal to the longitudinal direction of the opening;
at least one intermediate key-top unit including
a projecting section projecting from the opening when the intermediate key-top unit is fitted in the opening, and
flanges projecting in opposite directions orthogonal to the longitudinal direction of the opening,
the intermediate key-top unit being provided such that a sum of lengths of the first, second, and intermediate key-top units in the longitudinal direction of the opening becomes substantially the same as a longitudinal length of the opening;
a first water-blocking sheet provided on a bottom of the first key-top unit, the bottom being opposite the projecting section;
a second water-blocking sheet provided on a bottom of the second key-top unit, the bottom being opposite the projecting section;
an intermediate water-blocking sheet provided on a bottom of the intermediate key-top unit, the bottom being opposite the projecting section, the intermediate water-blocking sheet having overlapping portions that overlap portions of some of the water-blocking sheets adjoining thereto when the first, second, and intermediate key-top units are fitted in the opening;
pressing portions provided on the casing and applying pressures to the overlapping portions by being in contact therewith;
switches provided on a board housed in the casing and in correspondence with the first, second, and intermediate key-top units;
a first pusher member provided between the first key-top unit and a corresponding one of the switches and configured to transmit to the switch a pressing force applied when the first key-top unit is pressed;
a second pusher member provided between the second key-top unit and another corresponding one of the switches and configured to transmit to the switch a pressing force applied when the second key-top unit is pressed; and
an intermediate pusher member provided between the intermediate key-top unit and the other corresponding switch and configured to transmit to the switch a pressing force applied when the intermediate key-top unit is pressed.
